(19) United States
(12) Patent Application Publication
(10) Pub. No.: US 2014/0218954 A1
(43) Pub. Date: Aug. 7, 2014

(54) LIGHT-EMITTING DEVICE PACKAGE MODULE

(71) Applicant: SAMSUNG ELECTRONICS CO., LTD., Suwon-si (KR)

(72) Inventors: Young-jeong YOON, Suwon-si (KR); Ki-won CHOI, Suwon-si (KR)

(73) Assignee: SAMSUNG ELECTRONICS CO., LTD., Suwon-si (KR)

(21) Appl. No.: 14/094,294

(22) Filed: Dec. 2, 2013

(30) Foreign Application Priority Data
Feb. 6, 2013 (KR) 10-2013-0013492

(51) Int. Cl. H01L 33/62; F21S 8/10; F21S 2/00

(52) U.S. Cl. CPC H01L 33/62; F21S 2/005; F21S 48/00
USPC 362/546; 362/375; 257/99

(57) ABSTRACT

Provided is a light-emitting device package module including a light-emitting device; a first circuit board receiving the light-emitting device, and electrically connected with the light-emitting device; and a second circuit board assembled with the first circuit board by using a connection member, and electrically connected with the first circuit board.

### CROSS-REFERENCE TO RELATED APPLICATIONS

This application claims the benefit of priority to Korean Patent Application No. 10-2013-0013492, filed on Feb. 6, 2013, in the Korean Intellectual Property Office, the entire contents of which are hereby incorporated by reference.

### TECHNICAL FIELD

The inventive concept relates to light-emitting device package modules.

### BACKGROUND

The inventive concept relates to a light-emitting device package module, and more particularly, to a light-emitting device package module that allows standardization of parts, whereby a production efficiency may be significantly increased.

A light-emitting diode (LED) is a semiconductor device capable of realizing various colors of light by forming an emission source via PN formation of a compound semiconductor. An LED device is advantageous in that the LED device has a long lifetime, may be small and light-weight, and may be driven by using a small voltage due to its strong light directivity. Also, the LED device is highly resistant to shock and vibration, does not require a preheating time and complicated driving, and may be packaged into various forms, so that the LED device may be modularized according to various applications such as various lighting apparatuses or display devices.

In a conventional light-emitting device package module, a complicated die casting structure or a bracket is used, and then a plurality of light-emitting devices are connected by using a flexible circuit board. The conventional light-emitting device package module has unnecessary parts such as the die casting structure, the bracket, the flexible circuit board, or the like. Moreover, complicated jigs are required to fix rivets or clip structures for combining the unnecessary parts, such that productivity significantly deteriorates.

Accordingly, a need exists for increasing productivity and to improve heat dissipation performance of an light-emitting device package module.

### SUMMARY

An aspect of the inventive concept relates to a light-emitting device package module including an light-emitting device; a first circuit board receiving the light-emitting device, and electrically connected with the light-emitting device; and a second circuit board assembled with the first circuit board by using a connection member, and electrically connected with the first circuit board.

The first circuit board may be a quadrangular plate, and the second circuit board may include a first-side second circuit board assembled at a first side of the first circuit board and a second-side second circuit board assembled at a second side of the first circuit board.

The second circuit board may be a multi-step plate including a first step portion having a first height; and a second step portion connected to the first step portion and having a second height.

The second circuit board may further include a sloped portion that slopes between the first step portion and the second step portion.

The sloped portion of the second circuit board may be assembled with the first step portion and the second step portion by using the connection member.

The connection member may include a forced-engagement protrusion unit disposed on the first circuit board; and a forced-engagement groove unit disposed on the second circuit board and engaged to the forced-engagement protrusion unit.

The forced-engagement protrusion unit may include one or more quadrangular protrusions and the forced-engagement groove unit may include one or more quadrangular grooves corresponding to the one or more quadrangular protrusions.

The connection member may include a through hole formed in the first circuit board and a through hole protrusion formed on the second circuit board and inserted into the through hole.

The connection member may be formed of at least one selected from the group consisting of a connection pin, a hinge, a screw, a bolt, a rivet, a connection belt, an adhesive, a welding agent, a snap button, a Velcro tape, a magnet, and a combination thereof.

The first circuit board may include a first wiring layer electrically connected to the light-emitting device, and a first connection terminal formed at an end of the first wiring layer, and the second circuit board may include a second connection terminal electrically connected to the first connection terminal, a second wiring layer electrically connected to the second connection terminal, and an external connection terminal disposed at an end of the second wiring layer and connected to an external power connector.

The first connection terminal and the second connection terminal may be contact-type terminals that are respectively disposed on a contact surface of the first circuit board and a contact surface of the second circuit board when the first circuit board and the second circuit board are assembled.

An electric power transfer medium may be arranged between the first connection terminal and the second connection terminal.

The light-emitting device package module may further include a heat dissipation member thermally contacting the light-emitting device and externally dissipating heat generated in the light-emitting device.

The light-emitting device package module may further include an elastic member disposed between the first circuit board and the second circuit board so as to lessen a shock and collision between the first circuit board and the second circuit board.

Another aspect of the inventive concept relates to a light-emitting device package module including a light-emitting device; a first circuit board receiving the light-emitting device; and a second circuit board assembled with the first circuit board using a connection member, wherein the second circuit board is a multi-step plate comprising a first step portion having a first height and a second step portion connected to the first step portion and having a second height.

Another aspect of the inventive concept relates to a lighting device having a light-emitting device package module; a frame; a transparent cover; a first circuit board receiving the light-emitting device; and a second circuit board assembled with the first circuit board using a connection member, wherein the second circuit board is a multi-step plate comprising a first step portion having a first height and a second step portion connected to the first step portion and having a second height; and wherein the frame and the transparent cover in combination define a space which houses the light-emitting device, the first circuit board and the second circuit board. The second circuit board may include a sloped portion between the first and second steps.

The light-emitting device may be configured to be disposed within an enclosure formed by the frame and the transparent cover based on at least one of the angle of the sloped portion and the shape of the sloped portion.

The lighting device may be a vehicle light including one of a head light, a rear light, a display light, an inner light and a guide light.

### BRIEF DESCRIPTION OF THE DRAWINGS

The foregoing and other features of the inventive concept will be apparent from more particular description of embodiments of the inventive concept, as illustrated in the accompanying drawings in which like reference characters may refer to the same or similar elements throughout the different views. The drawings are not necessarily to scale, emphasis instead being placed upon illustrating the principles of the embodiments of the inventive concept. In the drawings, the thickness of layers and regions may be exaggerated for clarity.

Exemplary embodiments of the inventive concept will be more clearly understood from the following detailed description taken in conjunction with the accompanying drawings in which:

FIG. 1 is a perspective view illustrating a light-emitting device package module according to an embodiment of the inventive concept;

FIG. 2 is a partial exploded perspective view magnifying and illustrating a first circuit board and a second circuit board of FIG. 1;

FIG. 3 is a partial exploded perspective view magnifying and illustrating a first circuit board and second circuit boards of a light-emitting device package module, according to another embodiment of the inventive concept;

FIG. 4 is a partial exploded perspective view magnifying and illustrating a first circuit board and second circuit boards of a light-emitting device package module, according to another embodiment of the inventive concept;

FIG. 5 is a top plan view illustrating a first circuit board and second circuit boards of a light-emitting device package module, according to another embodiment of the inventive concept;

FIG. 6 is a top plan view illustrating a first circuit board and second circuit boards of a light-emitting device package module, according to another embodiment of the inventive concept;

FIG. 7 is a front elevation view of the light-emitting device package module of FIG. 6;

FIGS. 8 through 16 are partial cross-sectional side views illustrating various types of a connection member of light-emitting device package modules according to other embodiments of the inventive concept;

FIG. 17 is a partial exploded perspective view magnifying and illustrating a first circuit board and a second circuit board of a light-emitting device package module, according to another embodiment of the inventive concept;

FIG. 18 is a perspective view illustrating a light-emitting device package module, according to another embodiment of the inventive concept;

FIG. 19 is a perspective view illustrating a light-emitting device package module, according to another embodiment of the inventive concept;

FIG. 20 is a perspective view illustrating a light-emitting device package module, according to another embodiment of the inventive concept;

FIG. 21 is a cross-sectional side view illustrating a light-emitting device package module and a vehicle light using the light-emitting device package module, according to another embodiment of the inventive concept;

FIG. 22 is a partial cross-sectional side view illustrating a structure of a circuit board of the light-emitting device package module, according to an embodiment of the inventive concept;

FIGS. 23A and 23B are cross-sectional side views illustrating a structure of a circuit board of a light-emitting module included in the light-emitting device package module, according to other embodiments of the inventive concept;

FIG. 24 is a cross-sectional side view illustrating a structure of a circuit board of a light-emitting module included in the light-emitting device package module, according to another embodiment of the inventive concept;

FIG. 25 is a cross-sectional side view illustrating a structure of a circuit board of a light-emitting module included in the light-emitting device package module, according to another embodiment of the inventive concept;

FIG. 26 is a partial cross-sectional side view illustrating a structure of a circuit board of a light-emitting module included in the light-emitting device package module, according to another embodiment of the inventive concept;

FIG. 27 is a partial cross-sectional side view illustrating a structure of a circuit board of a light-emitting module included in the light-emitting device package module, according to another embodiment of the inventive concept;

FIG. 28 is a cross-sectional side view illustrating a structure of a meta sash to which the light-emitting module included in the light-emitting device package module is mounted, according to an embodiment of the;

FIG. 29 illustrates a color temperature spectrum related to light that is emitted from a light-emitting diode (LED) of the light-emitting device package module, according to an embodiment of the inventive concept;

FIG. 30 illustrates a structure of a quantum dot that may be used in an LED of the light-emitting device package module, according to an embodiment of the inventive concept;

FIG. 31 illustrates phosphor types according to application fields of a white light-emitting device using a blue-light LED in the light-emitting device package module, according to an embodiment of the inventive concept;

FIG. 32 is a cross-sectional side view illustrating an LED chip that may be used in the light-emitting device package module, according to an embodiment of the inventive concept;

FIG. 33 is a cross-sectional side view illustrating an LED chip that may be used in the light-emitting device package module, according to another embodiment of the inventive concept;

FIG. 34 is a cross-sectional side view illustrating an LED chip that may be used in the light-emitting device package module, according to another embodiment of the inventive concept;

FIG. 35 is a cross-sectional side view illustrating a semiconductor light-emitting device that includes an LED chip mounted at a substrate and that may be used in the light-emitting device package module, according to an embodiment of the inventive concept; and

FIG. 36 is a cross-sectional side view illustrating an LED package that may be used in the light-emitting device package module, according to an embodiment of the inventive concept.

### DETAILED DESCRIPTION OF THE EMBODIMENTS

The inventive concept will now be described more fully with reference to the accompanying drawings, in which exemplary embodiments of the inventive concept are shown. The inventive concept may, however, be embodied in many different forms and should not be construed as being limited to the embodiments set forth herein. Rather, these embodiments are provided so that this disclosure will be thorough and complete, and will fully convey the inventive concept to those of ordinary skill in the art.

Throughout the specification, it will also be understood that when an element such as layer, region, or substrate is referred to as being “on”, “connected to”, “stacked” or “coupled with” another element, it can be directly on the other element, or intervening elements may also be present. However, when an element is referred to as being “directly on”, “directly connected to”, “directly stacked” or “directly coupled with” another element, it will be understood that there are no intervening elements. Like reference numerals denote like elements. Throughout the specification, a term “and/or” includes at least one from among all listed components and one or more combinations of all listed components.

While terms “first” and “second” are used to describe various components, parts, regions, layers and/or portions, it is obvious that the components, parts, regions, layers and/or portions are not limited to the terms “first” and “second”. The terms “first” and “second” are used only to distinguish between each of components, each of parts, each of regions, each of layers and/or each of portions. Thus, throughout the specification, a first component, a first part, a first region, a first layer or a first portion may indicate a second component, a second part, a second region, a second layer or a second portion without conflicting with the inventive concept.

Spatially relative terms, such as “below” or “lower” and the like, may be used herein for ease of description to describe the relationship of one element or feature to another element(s) or feature(s) as illustrated in the figures. It will be understood that the spatially relative terms are intended to encompass different orientations of the device in use or operation, in addition to the orientation depicted in the figures. For example, if the device in the figures is turned over, elements described as “below” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

Furthermore, all examples and conditional language recited herein are to be construed as being without limitation to such specifically recited examples and conditions. Throughout the specification, a singular form may include plural forms, unless there is a particular description contrary thereto. Also, terms such as “comprise” or “comprising” are used to specify existence of a recited form, a number, a process, an operations, a component, and/or groups thereof, not excluding the existence of one or more other recited forms, one or more other numbers, one or more other processes, one or more other operations, one or more other components and/or groups thereof.

Hereinafter, the inventive concept will be described in detail by explaining exemplary embodiments of the inventive concept with reference to the attached drawings. With respect to the drawings, shapes in the drawings may be revised according to a manufacturing technology and/or a tolerance. Therefore, the attached drawings for illustrating exemplary embodiments of the inventive concept are referred to in order to gain a sufficient understanding of the inventive concept, the merits thereof, and the objectives accomplished by the implementation of the inventive concept.

Expressions such as “at least one of,” when preceding a list of elements, modify the entire list of elements and do not modify the individual elements of the list.

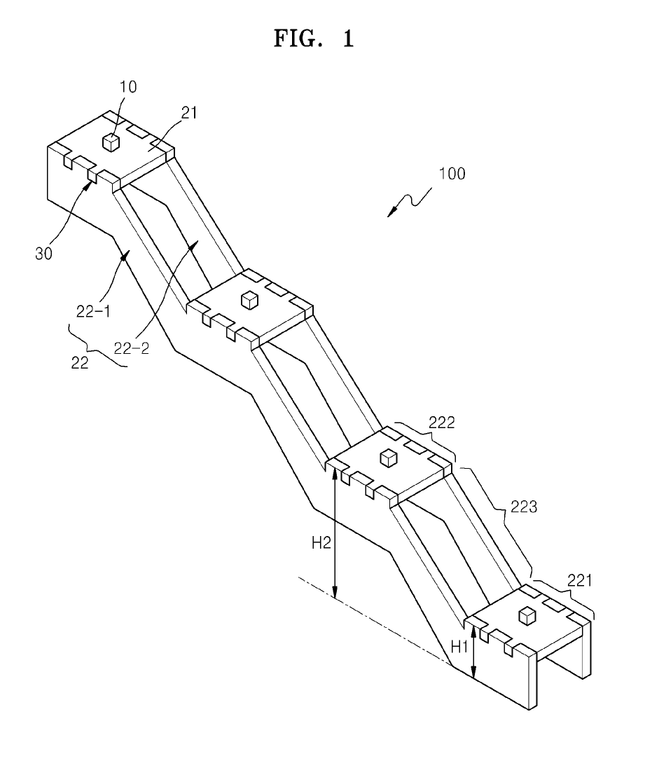

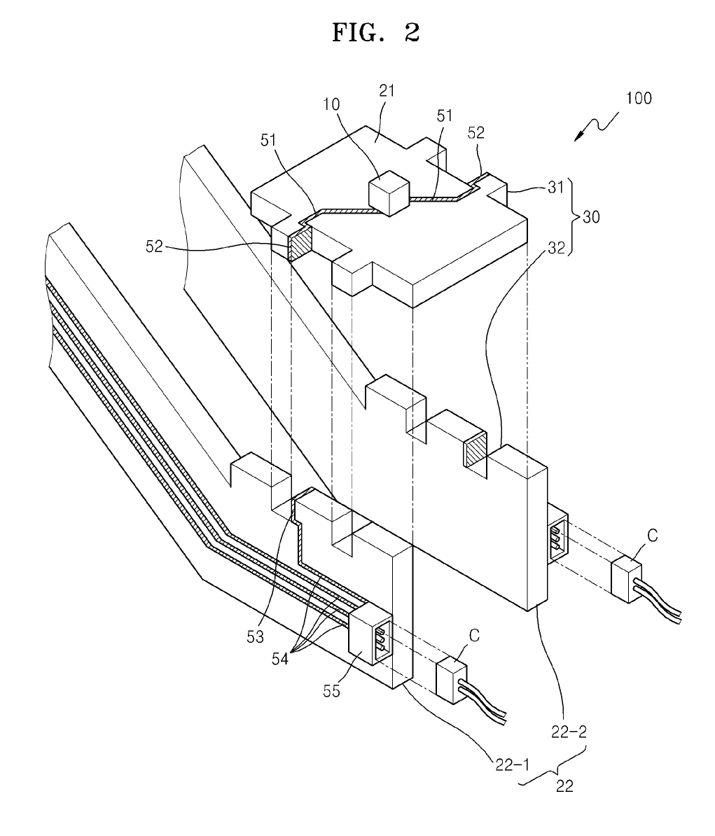

As illustrated in FIGS. 1 and 2, a light-emitting device package module 100 may include a light-emitting device 10, a first circuit board 21, and a second circuit board 22.

Here, as illustrated in FIGS. 1 and 2, the light-emitting device 10 may be mounted on the first circuit board 21 and may be formed of a semiconductor. For example, the light-emitting device 10 may be formed of a blue-color light-emitting diode (LED), an ultraviolet ray LED, or the like, which is formed of a nitride semiconductor. The nitride semiconductor may be represented by the general formula: AlₓGa_{y}In_{z}N(0≦x≦1, 0≦y≦1, 0≦z≦1, X+Y+Z=1).

Also, the light-emitting device 10 may be formed in a manner in which a nitride semiconductor such as InN, MN, InGaN, AlGaN, or InGaAlN is epitaxially grown on a substrate by using a vapor-phase growing method such as metal organic chemical vapor deposition (MOCVD). Also, the light-emitting device 10 may be formed by using a semiconductor other than the nitride semiconductor, such as a ZnO, ZnS, ZnSe, SiC, GaP, GaAlAs, or AlInGaP semiconductor. Each of the aforementioned semiconductors may be formed as a multilayer body in which an n-type semiconductor layer, an emission layer, and a p-type semiconductor layer are sequentially stacked. The emission layer (i.e., an active layer) may be formed as a stack semiconductor having a multi-quantum well structure or a single-quantum well structure, or a stack semiconductor having a double-hetero structure. Alternatively, the light-emitting device 10 may be formed of LEDs having a predetermined wavelength.

The first circuit board 21 may receive or accommodate the light-emitting device 10, may be electrically connected with the light-emitting device 10, and may be formed of a material having a mechanical strength and an insulation property that are good enough to support the light-emitting device 10.

For example, the first circuit board 21 may have various wiring layers to connect the light-emitting device 10 and an external power source, and may be a printed circuit board (PCB) in which a plurality of epoxy-based resin sheets are stacked. Also, the first circuit board 21 may be formed of a synthetic resin substrate including resin, glass epoxy, or the like, a ceramic substrate in consideration of a thermal conductivity, or a metal substrate including aluminium, copper, zinc, tin, gold, silver, or the like that are insulation-processed. A plate-shaped substrate or a lead frame-shaped substrate may be applied to the first circuit board 21.

Also, as illustrated in FIGS. 1 and 2, the second circuit board 22 may be assembled with the first circuit board 21 by using a connection member 30 having various shapes, and may be electrically connected to the first circuit board 21.

The second circuit board 22 may be formed of a material having a mechanical strength and an insulation property that are good enough to support the first circuit board 21.

For example, the second circuit board 22 may have various wiring layers to connect the first circuit board 21 and an external power source, and may be a PCB in which a plurality of epoxy-based resin sheets are stacked. Also, the second circuit board 22 may be formed of a synthetic resin substrate including resin, glass epoxy, or the like, a ceramic substrate in consideration of a thermal conductivity, or a metal substrate including aluminium, copper, zinc, tin, gold, silver, or the like that are insulation-processed. A plate-shaped substrate or a lead frame-shaped substrate may be applied to the second circuit board 22. The material that forms the second circuit board 22 may be the same or different than the material that forms the first circuit board 21. Here, the different materials are materials that are entirely different from each other in their types and compositions.

Also, as illustrated in FIGS. 1 and 2, the first circuit board 21 may be a quadrangular plate. Also, the second circuit board 22 may include a left-side second circuit board 22-1 assembled at a left side of the first circuit board 21 and a right-side second circuit board 22-2 assembled at a right side of the first circuit board 21.

Also, as illustrated in FIG. 1, the second circuit board 22 may be a multi-step plate including a first step portion 221 having a first height H1 and a second step portion 222 connected to the first step portion 221 and having a second height H2.

Also, as illustrated in FIG. 1, the second circuit board 22 may further include a sloped portion 223 that slopes between the first step portion 221 and the second step portion 222.

Referring to FIG. 1, the light-emitting device 10 is not mounted on the second circuit board 22, but according to an embodiment, the light-emitting device 10 may be mounted on the second circuit board 22.

As illustrated in FIG. 2, the connection member 30 allows the first circuit board 21 and the second circuit board 22 to be coupled with each other and then to maintain their assembled state. The connection member 30 may include a forced-engagement protrusion unit 31 formed on the first circuit board 21, and a forced-engagement groove unit 32 formed on the second circuit board 22 and engaged to the forced-engagement protrusion unit 31.

Here, as illustrated in FIG. 2, the forced-engagement protrusion unit 31 may include a plurality of quadrangular protrusions, and the forced-engagement groove unit 32 may include a plurality of quadrangular grooves engaged to the quadrangular protrusions in the form of teeth.

While it is described that the forced-engagement protrusion unit 31 and the forced-engagement groove unit 32 have the quadrangular protrusions and grooves, the present embodiment is not limited thereto. Thus, the forced-engagement protrusion unit 31 and the forced-engagement groove unit 32 may have various shapes such as a circular shape, a pentagonal shape, a wave shape, a polygonal shape, or the like that allow mutual engagement.

Thus, as illustrated in FIG. 2, in a procedure of assembling the first circuit board 21 and the second circuit board 22, the forced-engagement protrusion unit 31 formed at the left side of the first circuit board 21 is forcibly inserted into the forced-engagement groove unit 32 formed above the left-side second circuit board 22-1. Then, the forced-engagement protrusion unit 31 formed at the right side of the first circuit board 21 is forcibly inserted into the forced-engagement groove unit 32 formed above the right-side second circuit board 22-2. Then a plurality of the first circuit boards 21 are assembled to the left-side second circuit board 22-1 and the right-side second circuit board 22-2, so that a solid and fixed structure may be formed.

As illustrated in FIG. 2, the first circuit board 21 may include a first wiring layer 51 electrically connected to the light-emitting device 10, and a first connection terminal 52 formed at an end of the first wiring layer 51.

Also, the second circuit board 22 may include a second connection terminal 53 electrically connected to the first connection terminal 52, a second wiring layer 54 electrically connected to the second connection terminal 53, and an external connection terminal 55 formed at an end of the second wiring layer 54 and connected to an external power connector C.

The first connection terminal 52 and the second connection terminal 53 may be contact-type terminals formed on contact surfaces of the first circuit board 21 and the second circuit board 22 when the first circuit board 21 and the second circuit board 22 are assembled.

Thus, as illustrated in FIG. 2, in an electrical connection procedure of the first circuit board 21 and the second circuit board 22, when the first circuit board 21 and the second circuit board 22 are assembled, the first connection terminal 52 and the second connection terminal 53 physically and electrically contact each other. Accordingly, an external electric power may be supplied to the light-emitting device 10 via the external power connector C, the external connection terminal 55, the second wiring layer 54, the second connection terminal 53, the first connection terminal 52, and the first wiring layer 51.

Thus, in the light-emitting device package module 100 according to the present embodiment, shapes of the first circuit boards 21 are constant so that parts may be standardized, and various forms of the second circuit board 22 are used so that a conventional procedure of manufacturing and assembling separate parts such as die casting structures is sharply decreased. Accordingly, production efficiency and part productivity may be improved and the part manufacturing costs and time may be reduced.

Also, when a lifetime of the light-emitting device 10 is ended, or a malfunction or error occur in the light-emitting device 10, the first circuit board 21 may be easily replaced without having to replace a whole module. Accordingly, the part replacing costs may be reduced. Also, since a wide air path is formed between the first circuit board 21 and the second circuit board 22, a product may have a good heat dissipation performance and be lightweight.

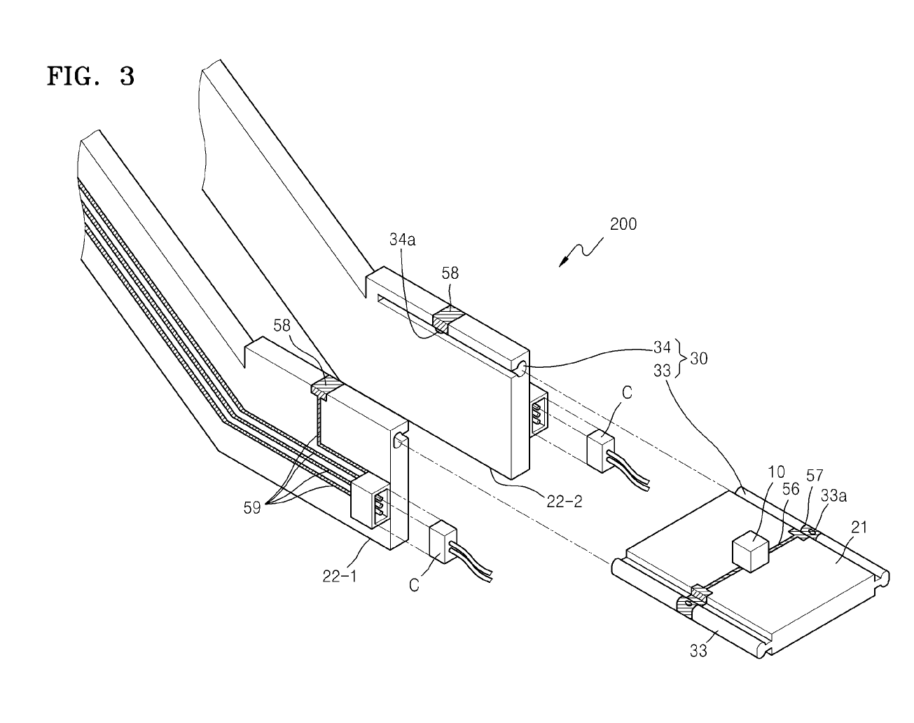

FIG. 3 illustrates a light-emitting device package module 200, according to another embodiment of the inventive concept.

A protrusion unit and a groove unit having various shapes may be formed, other than the forced-engagement protrusion unit 31 and the forced-engagement groove unit 32 of FIG. 2.

That is, as illustrated in FIG. 3, a forced-engagement protrusion unit 33 may be at least one plane-type protrusion unit, and a forced-engagement groove unit 34 may be at least one plane-type groove unit that corresponds to the forced-engagement protrusion unit 33.

Thus, the first circuit board 21 and the left-side and right-side second circuit boards 22-1 and 22-2 of the light-emitting device package module 100 of FIG. 2 are coupled with each other in a vertical direction, whereas the first circuit board 21 and the second circuit boards 22-1 and 22-2 of the light-emitting device package module 200 of FIG. 3 are coupled with each other in a horizontal direction that is in a front-rear direction.

Here, as illustrated in FIG. 3, an auxiliary forced-engagement groove 33a may be formed at the forced-engagement protrusion unit 33, and an auxiliary forced-engagement protrusion 34a corresponding to the auxiliary forced-engagement groove 33a may be formed at the forced-engagement groove unit 34.

The auxiliary forced-engagement groove 33a may be formed at a first connection terminal 57 formed at an end of a first wiring layer 56 electrically connected to the light-emitting device 10. The auxiliary forced-engagement protrusion 34a that corresponds to the auxiliary forced-engagement groove 33a may be formed at a second connection terminal 58 formed at an end of a second wiring layer 59.

Thus, while an operator horizontally inserts the forced-engagement protrusion unit 33 of the first circuit board 21 into the forced-engagement groove unit 34 of the second circuit board 22, when the auxiliary forced-engagement protrusion 34a reaches the auxiliary forced-engagement groove 33a, the operator may sense an electrical connection between the auxiliary forced-engagement protrusion 34a and the auxiliary forced-engagement groove 33a via clicking sound or vibration.

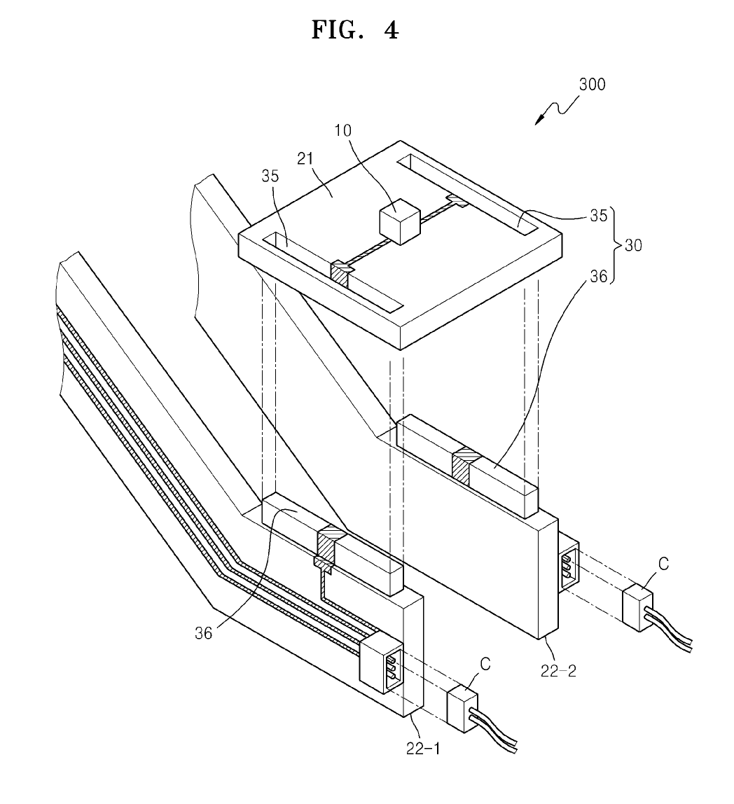

FIG. 4 illustrates a light-emitting device package module 300, according to another embodiment of the inventive concept.

As illustrated in FIG. 4, the connection member 30 may include a through hole 35 formed in the first circuit board 21, and a through hole protrusion 36 formed on the second circuit board 22 and inserted into the through hole 35.

Thus, since the through hole protrusion 36 is vertically inserted into and fixed at the through hole 35, if an external force is horizontally applied to the first circuit board 21 or the second circuit boards 22-1 and 22-2, the first circuit board 21 and the second circuit boards 22-1 and 22-2 may firmly maintain their coupled state.

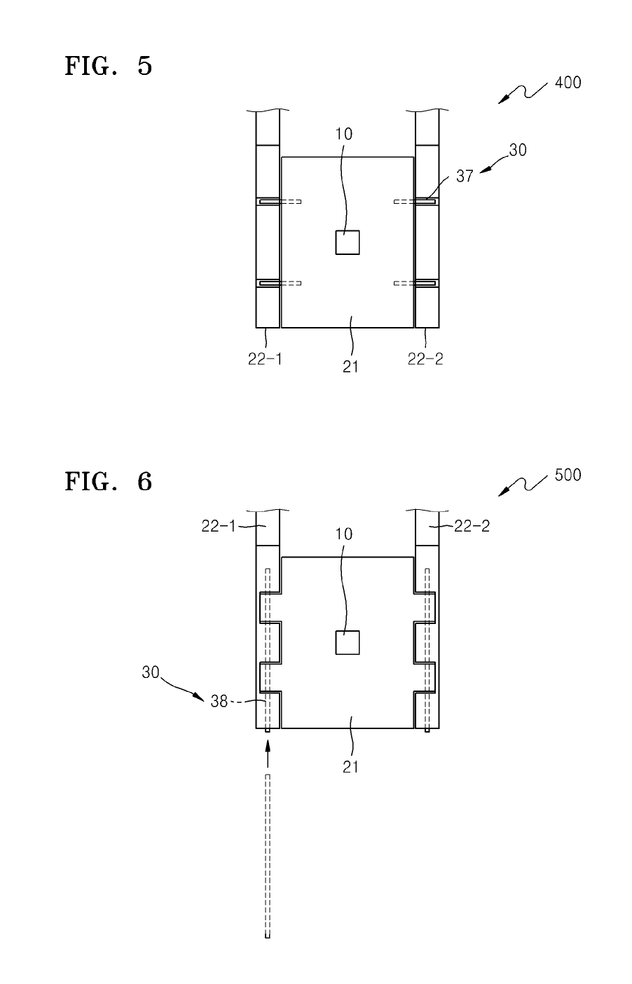

FIG. 5 illustrates a light-emitting device package module 400, according to another embodiment of the inventive concept.

As illustrated in FIG. 5, connection pins 37 arranged in a first horizontal direction may be used as the connection member 30. The connection pins 37 may be fixed at the first circuit board 21, and may penetrate through the second circuit boards 22-1 and 22-2.

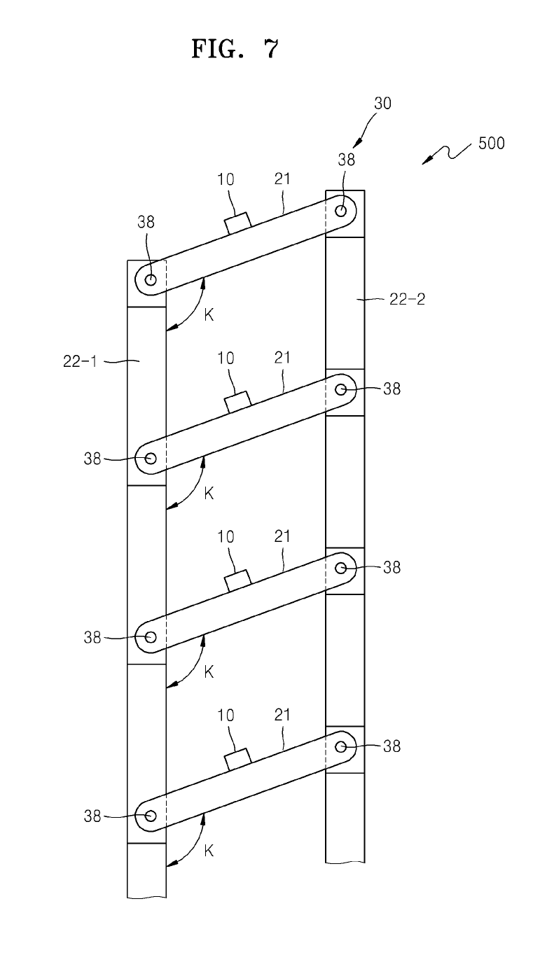

FIGS. 6 and 7 illustrate a light-emitting device package module 500, according to another embodiment of the inventive concept.

As illustrated in FIGS. 6 and 7, a hinge 38 arranged in a second horizontal direction may be used as the connection member 30. Due to the hinge 38, as illustrated in FIG. 7, the first circuit board 21 and the second circuit board 22-1 may be coupled by a free angle K when assembled.

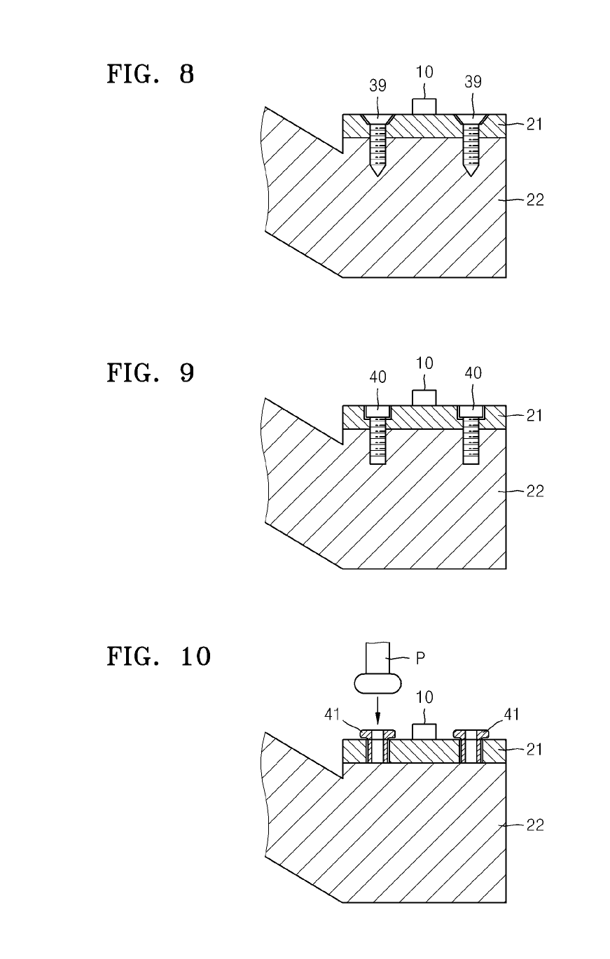

FIGS. 8 through 16 illustrate various types of the connection member 30 of light-emitting device package modules according to other embodiments of the inventive concept.

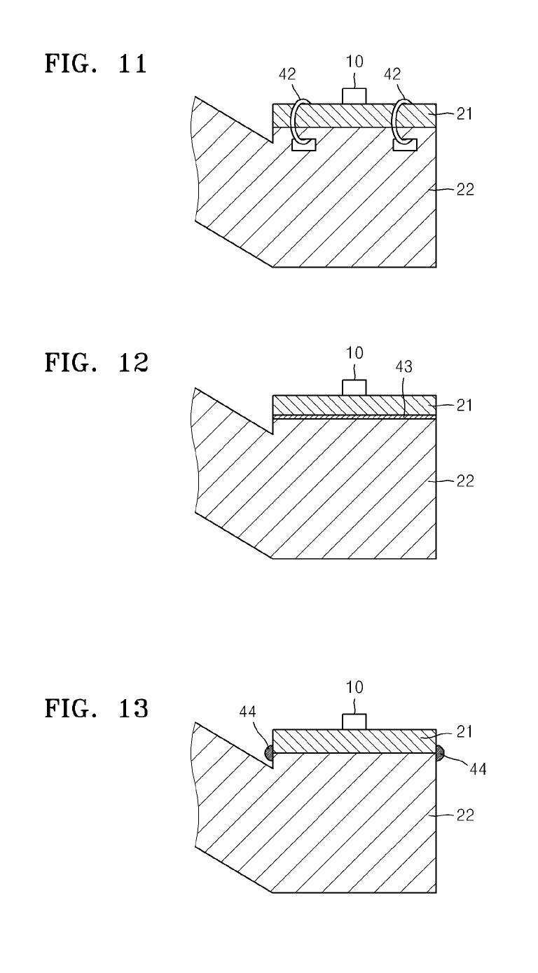

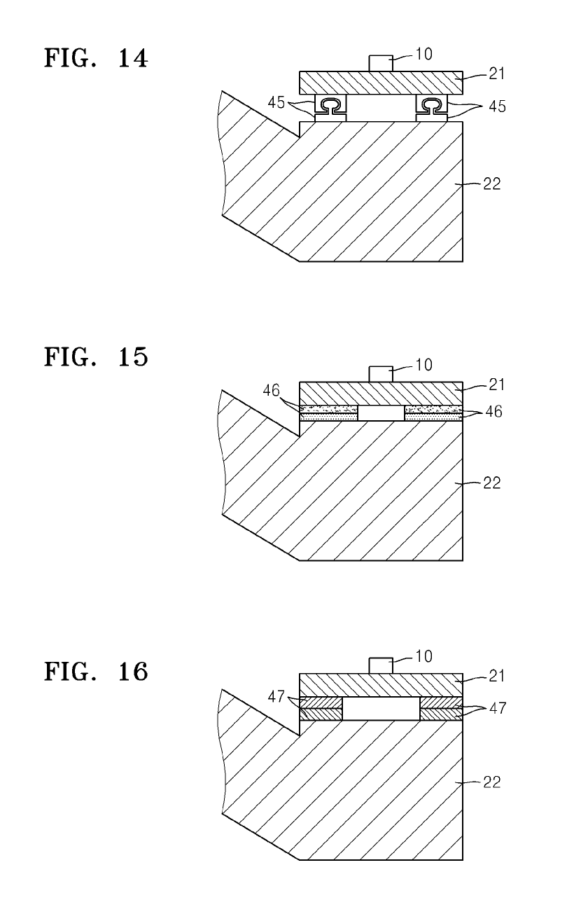

That is, the connection member 30 mutually connecting the first circuit board 21 and the second circuit board 22 may be formed of at least one selected from the group consisting of a screw 39 illustrated in FIG. 8, a bolt 40 illustrated in FIG. 9, a rivet 41 illustrated in FIG. 10 and that is assembled and pressed by a press P, a connection belt 42 illustrated in FIG. 11, an adhesive 43 illustrated in FIG. 12, a welding agent 44 illustrated in FIG. 13, a snap button 45 illustrated in FIG. 14, a Velcro tape 46 illustrated in FIG. 15, a magnet 47 illustrated in FIG. 16, and any combination thereof.

The various types of the connection member 30 may be optimally used according to a shape, a type, a material, or other design conditions of the light-emitting device 10, the first circuit board 21, and the second circuit board 22.

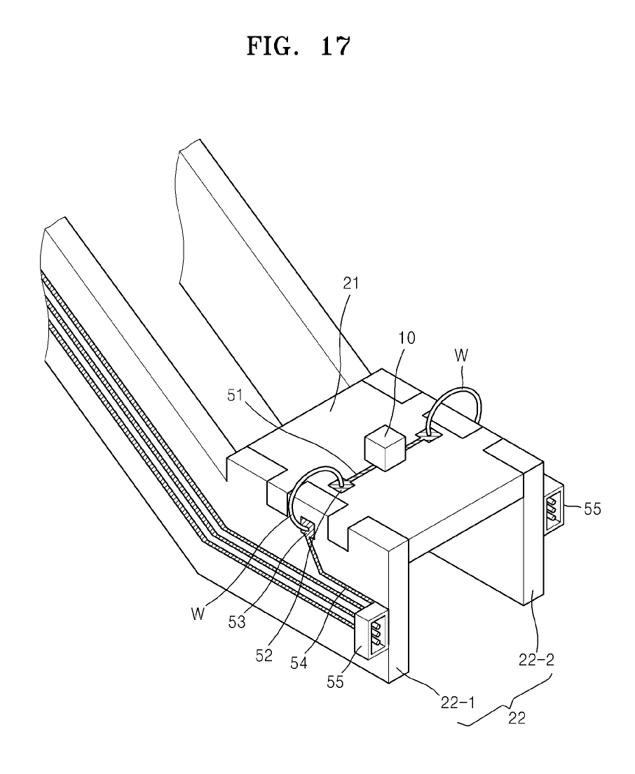

FIG. 17 illustrates a light-emitting device package module 600, according to another embodiment of the inventive concept.

As illustrated in FIG. 17, separately from the connection member 30, an electric power transfer medium such as a wire W, a bump, a solder ball, or the like may be arranged between the first connection terminal 52 and the second connection terminal 53.

Here, the wire W is used to bond a semiconductor device. The wire W may be formed of gold (Au), silver (Ag), platinum (Pt), aluminum (Al), copper (Cu), palladium (Pd), nickel (Ni), cobalt (Co), chrome (Cr), titanium (Ti), or the like, and may be formed by using a wire bonding apparatus.

Also, the bump or the solder ball may be formed of Au, Pt, Al, Cu, solder, or the like via a procedure including various deposition processes, a sputtering process, a plating process including pulse plating or direct current plating, a soldering process, an adhesion process, or the like.

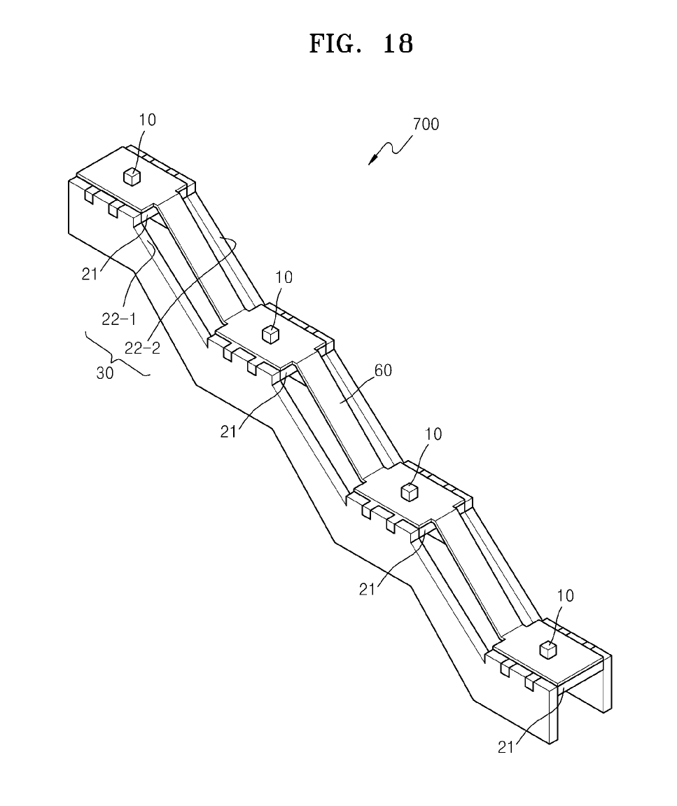

FIG. 18 is a part assembly perspective view illustrating a light-emitting device package module 700, according to another embodiment of the inventive concept.

As illustrated in FIG. 18, the light-emitting device package module 700 may further include a heat dissipation member 60 thermally contacting the light-emitting device 10 and that externally dissipates heat generated in the light-emitting device 10. Thus, the heat generated in a plurality of the light-emitting devices 10 may be transferred along the heat dissipation member 60 and then may be easily dissipated to outside air.

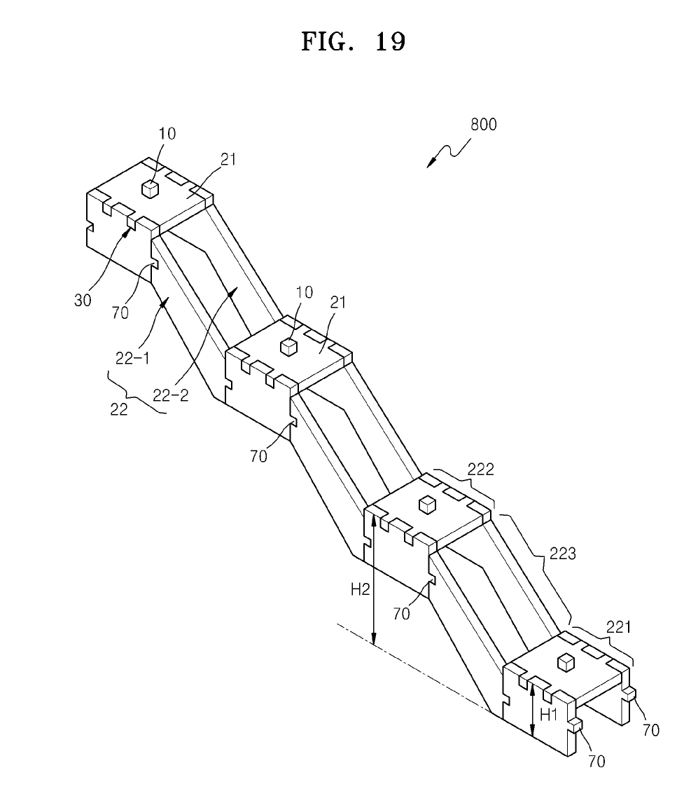

FIG. 19 illustrates a light-emitting device package module 800, according to another embodiment of the inventive concept.

As illustrated in FIG. 19, a sloped portion 223 of a second circuit board 22 may be assembled with a first step portion 221 and a second step portion 222 by using a connection member 70. Here, the connection member 70 may correspond to the various types of the connection member 30 that are described with reference to FIGS. 1 through 16.

Thus, as illustrated in FIG. 19, the second circuit board 22 may be disassembled into a plurality of block pieces or may be assembled. In particular, the first step portion 221 and the second step portion 222 may be assembled with various types of the sloped portion 223 that slopes with various angles, so that the first step portion 221 and the second step portion 222 may be easily changed to various shapes that are required according to a design.

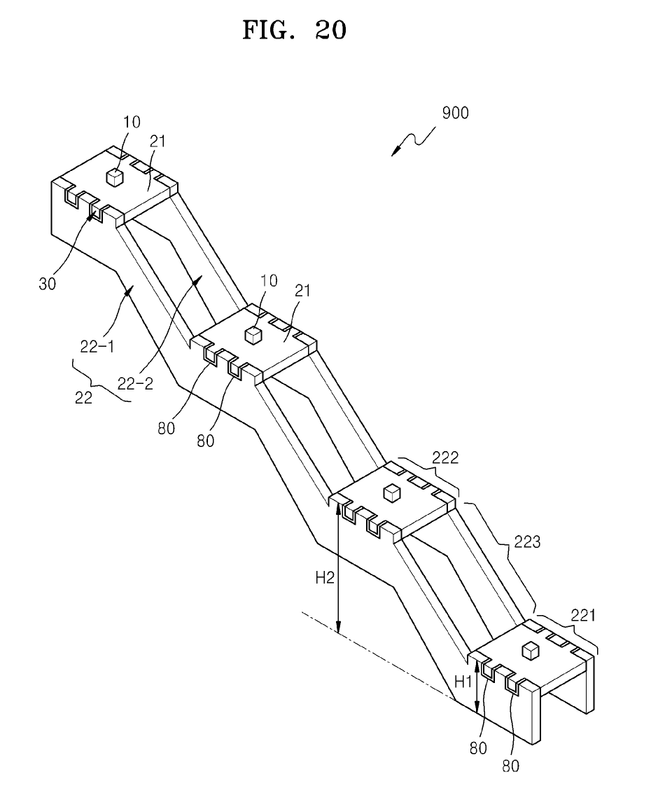

FIG. 20 illustrates a light-emitting device package module 900, according to another embodiment of the inventive concept.

As illustrated in FIG. 20, the light-emitting device package module 900 may further include an elastic member 80 that is formed between a first circuit board 21 and a second circuit board 22 so as to lessen a shock and collision between the first circuit board 21 and the second circuit board 22. Here, the elastic member 80 may be formed of a natural or synthetic resin-based material having an elasticity that is good enough for external deformation. For example, rubber, silicon, urethane, various types of expandable resin, or the like may be used to form the elastic member 80. Thus, the elastic member 80 may enforce physical coupling between the first circuit board 21 and the second circuit board 22, or may smooth an external shock and external collision, so that the elastic member 80 may improve durability of parts and may decrease noise and vibration that occur between parts.

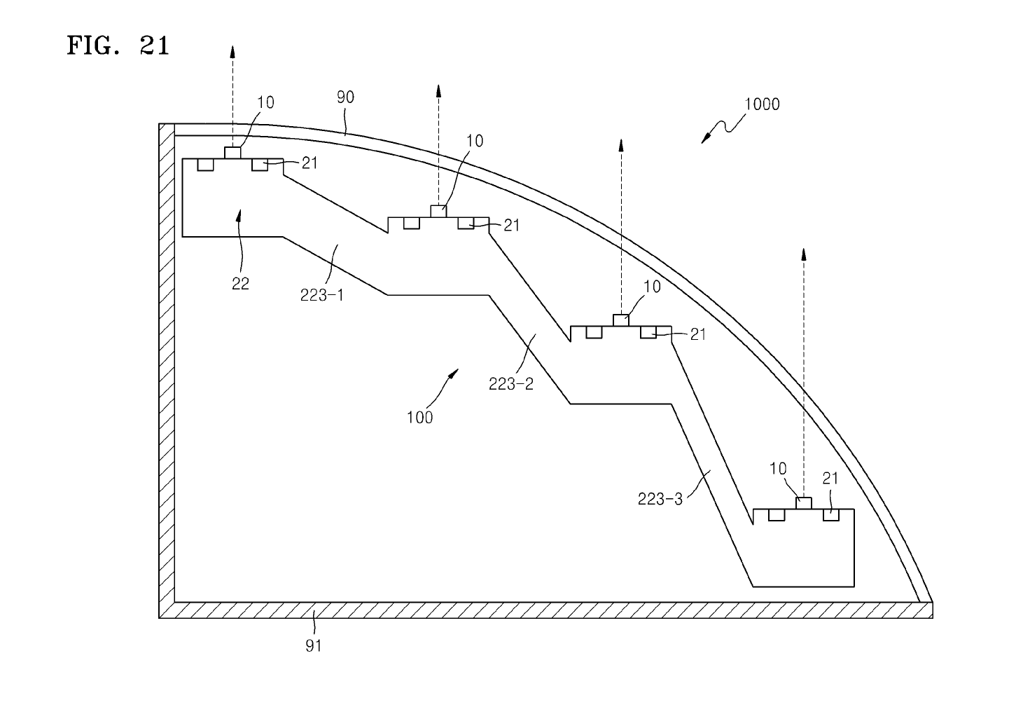

FIG. 21 illustrates a vehicle light 1000 using the light-emitting device package module 100, according to another embodiment of the inventive concept.

As illustrated in FIG. 21, the light-emitting device package module 100 may be assembled with a transparent cover 90 formed of glass or transparent resin, and a frame 91, so that the light-emitting device package module 100 may form the vehicle light 1000, such as a head light or a rear light of a vehicle.

Here, the light-emitting device package module 100 may be applied in various forms according to vehicle designs, by using sloped portions 223-1, 223-2, and 223-3 formed with various angles and having various shapes.

In addition, the light-emitting device package module 100 may be broadly used in various lighting apparatuses such as a head light, a rear light, a display light, an inner light, a guide light, or the like mounted inside and outside the vehicle, and various lighting apparatuses mounted in houses, factories, companies, or cities, or other display devices.

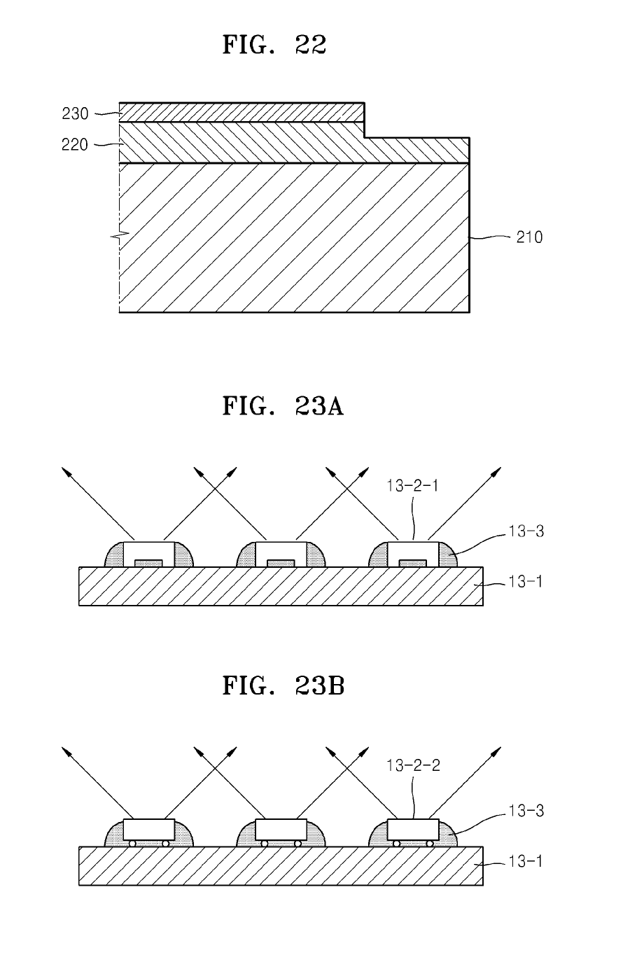

FIG. 22 through FIG. 27 illustrate structures of a circuit board of the light-emitting device package module, according to embodiments of the inventive concept;

The first circuit board 21 and the second circuit board 22 may be formed as a metal plate as shown in FIG. 22.

As illustrated in FIG. 22, the metal plate may include a structure in which an insulating layer 220 is formed on a first metal layer 210, and a second metal layer 230 is formed on the insulating layer 220. A stepped region to expose the insulating layer 220 may be formed at a side end of the metal plate.

The first metal layer 210 may be formed of a material having an excellent heat characteristic. For example, the first metal layer 210 may be formed of Al or Fe or an alloy thereof and may have a single-layer structure or a multi-layer structure. The insulating layer 220 may be formed of an inorganic or organic material having an insulation characteristic. For example, the insulating layer 220 may be formed of an epoxy-based insulation resin, and in order to improve its thermal conductivity, the epoxy-based insulation resin may include a metal powder such as an Al powder. In general, the second metal layer 230 may be formed as a Cu thin film layer.

For example, as illustrated in FIGS. 23A and 23B, each of the first circuit board 21 and the second circuit board 22 may be a circuit board in which an LED chip 13-2-1 is directly mounted on a PCB 13-1 (e.g., substrate), or a package 13-2-2 having a chip is mounted on the PCB 13-1 (e.g., substrate) and a waterproof agent 13-3 surrounds the package 13-2-2.

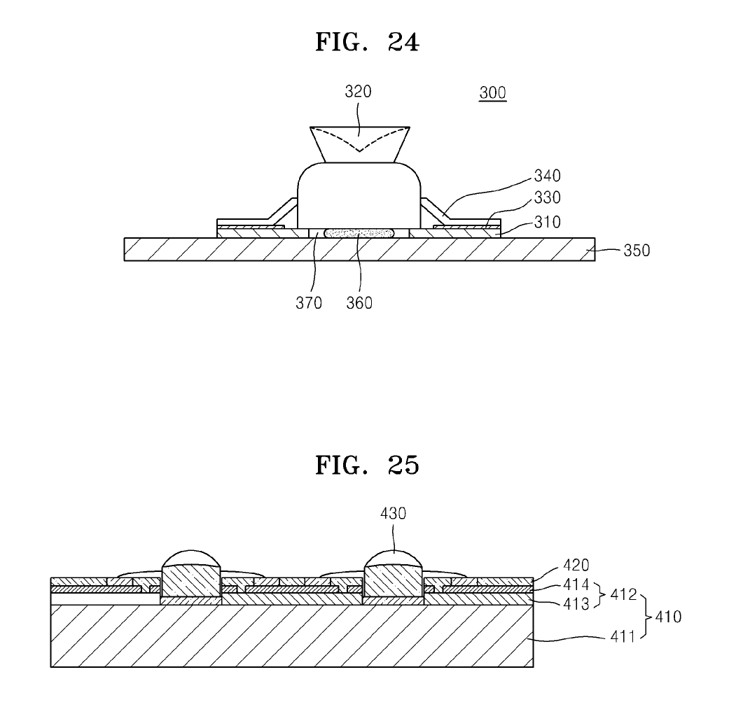

For example, each of the first circuit board 21 and the second circuit board 22 may include a substrate as shown in FIG. 24.

As illustrated in FIG. 24, a flexible substrate may be provided as a slim-type substrate unit capable of decreasing a thickness and a weight of each of the first circuit board 21 and the second circuit board 22, reducing the manufacturing costs, and increasing heat dissipation efficiency.

The slim-type substrate unit may include a circuit board having one or more through holes formed therein, and LED chips or packages coupled onto the circuit board via the one or more through holes, respectively. By using the flexible substrate as a substrate material of the slim-type substrate unit, the thickness and weight may be decreased so that slimness and light-weight may be achieved and the manufacturing costs may be reduced. Since the LED chip or the package is directly coupled to a supporting substrate by using a heat dissipation adhesive, dissipation efficiency of heat that is generated in the LED chip or the package may be improved.

Referring to FIG. 24, the flexible substrate may include a flexible PCB 310 in which at least one through hole 370 is formed, an adhesion layer 330, a supporting layer 340 for supporting a LED chip or package 320 coupled onto the flexible PCB 310 via the at least one through hole 370, a supporting substrate 350 to which the flexible PCB 310 is mounted, and a heat dissipation adhesive 360 arranged in the at least one through hole 370 so as to couple a bottom surface of the LED chip or package 320 with a top surface of the supporting substrate 350. The bottom surface of the LED chip or package 320 may be a bottom surface of a chip package whose bottom surface of an LED chip is directly exposed, a bottom surface of a lead frame having a top surface to which a chip is mounted, a metal block or the like.

For example, each of the first circuit board 21 and the second circuit board 22 may include a substrate as shown in FIG. 25.

As illustrated in FIG. 25, a circuit board 410 may have a structure in which a resin coating copper clad laminate (RCC) 412 formed of an insulating layer 413 and a copper thin film layer 414 stacked on the insulating layer 413. RCC 412 is stacked on a heat dissipation substrate 411, and a protective layer 420 that is formed of a liquid photo solder resistor (PSR) is stacked on the copper thin film layer 414 (e.g., a circuit layer). A portion of the RCC 412 may be removed, so that a metal copper clad laminate (MCCL) having at least one groove to which an LED chip or package 430 is mounted may be formed. In the circuit board 410, an insulating layer at a lower region of the LED chip or package 430 to which a light source is received is removed, so that the light source contacts a heat dissipation substrate 411 and heat generated in the light source is directly transferred to the heat dissipation substrate 411. Thus a heat dissipation performance may be improved.

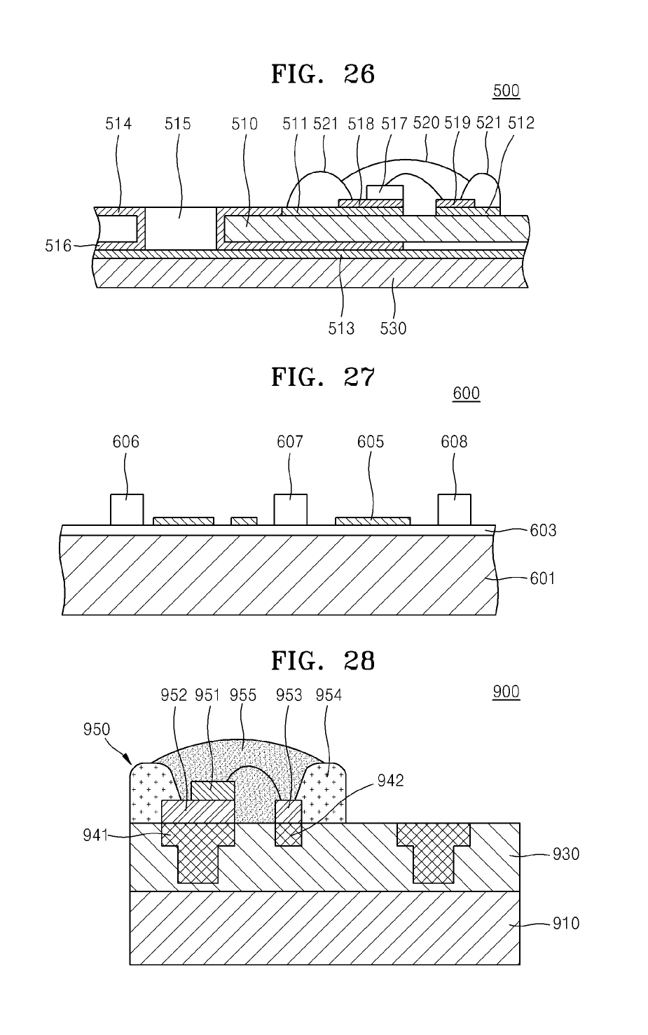

For example, each of the first circuit board 21 and the second circuit board 22 of an LED module 500 may include a substrate as shown in FIG. 26.

As illustrated in FIG. 26, a circuit board 510 may include an insulation substrate and may have a structure in which circuit patterns 511 and 512 formed of a copper laminate may be formed on a top surface of the insulation substrate, and an insulation thin film layer 513 thinly coated with an insulation material may be formed on a bottom surface of the insulation substrate, which is formed on a chassis 530. Here, various coating methods such as a sputtering method or a spraying method may be used. Also, top and bottom heat diffusion plates 514 and 516 may be formed on the top and bottom surfaces of the circuit board 510 so as to dissipate heat generated in an LED module. In particular, the top heat diffusion plate 514 directly contacts the circuit pattern 511. For example, the insulation material that is used as the insulation thin film layer 513 has thermal conductivity that is significantly lower than that of a heat pad, but since the insulation thin film layer 513 has a very small thickness, the insulation thin film layer 513 may have a thermal resistance that is significantly lower than that of the heat pad. The heat that is generated in the LED module may be transferred to the bottom heat diffusion plate 516 via the top heat diffusion plate 514 and then may be dissipated.

Two through holes 515 may be formed in the circuit board 510 and the top and bottom heat diffusion plates 514 and 516 so as to be vertical to the circuit board 510. The LED package may include an LED chip 517, LED electrodes 518 and 519, a plastic molding case 521, a lens 520, or the like. The circuit board 510 may have a circuit pattern formed by laminating a copper layer onto an FR4-core that is a ceramic or epoxy resin-based material and then by performing an etching process.

The LED module may have a structure in which at least one of a red-light LED that emits red light, a green-light LED that emits green light, and a blue-light LED that emits blue light is mounted, and at least one type of a phosphor material may be coated on a top surface of the blue-light LED.

The phosphor material may be sprayed while including a particle powder mixed with a resin. The phosphor powder may be fired and thus may be formed in the form of a ceramic plate layer on the top surface of the blue-light LED. A size of the phosphor powder may be from 1 um to 50 um, more preferably, from Sum to 20 um. In a case of a nano phosphor, it may be a quantum dot having a size of from 1 to 500 nm, more preferably, from 10 nm to 50 nm.

For example, each of the first circuit board 21 and the second circuit board 22 may include a metal substrate 600 as shown in FIG. 27.

As illustrated in FIG. 27, the metal substrate 600 may include a metal plate 601 that is formed of Al (Aluminum) or an Al alloy, and an Al anodized layer 603 that is formed on a top surface of the metal plate 601. Heat generation devices 606, 607, 608 such as LED chips may be mounted on the metal plate 601. The Al anodized layer 603 may insulate a wiring 605 from the metal plate 601.

The metal substrate 600 may be formed of Al or an Al alloy that is relatively less expensive. Alternatively, the metal substrate 600 may be formed of another material such as titanium or magnesium that may be anodized.

The Al anodized layer 603 that is obtained by anodizing Al has a relatively high heat transfer characteristic of about 10 through 30 W/mK. Thus, the metal substrate 600 including the Al anodized layer 603 may have a heat dissipation characteristic that is more excellent that that of a polymer substrate-based PCB or an MCPCB according to the related art.

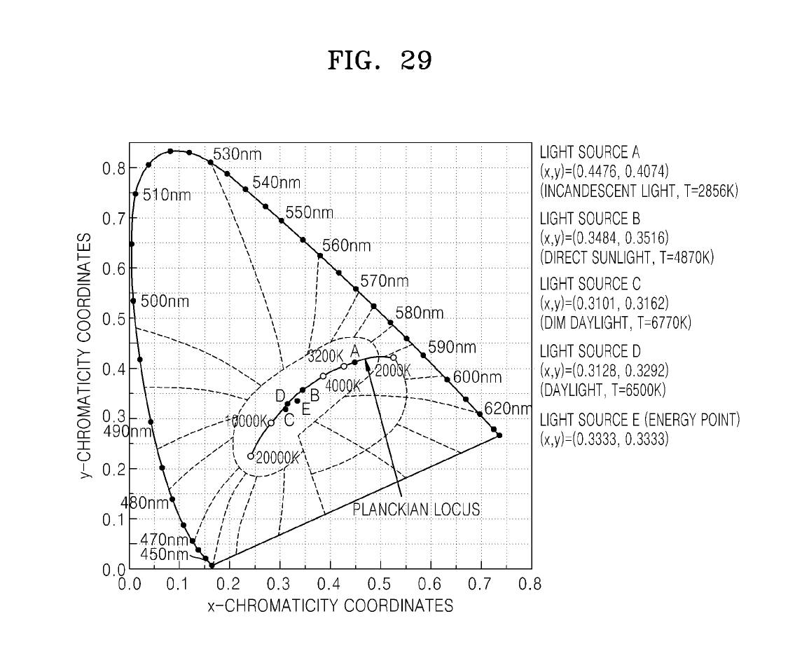

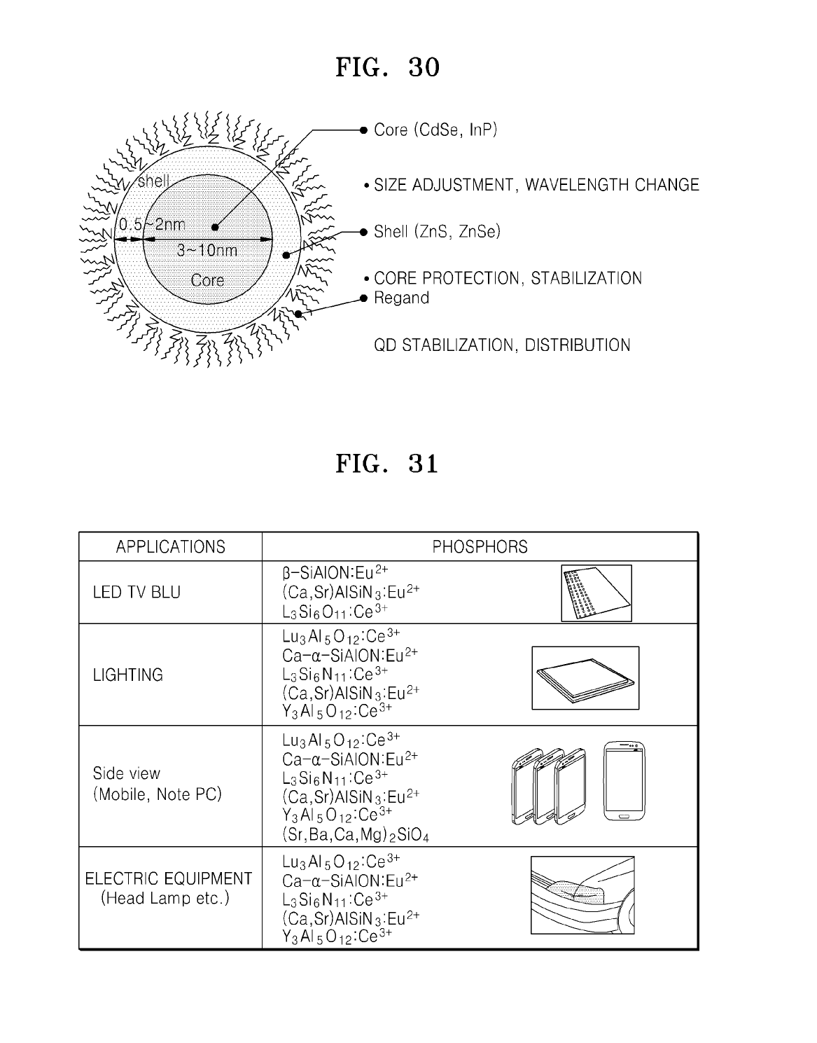

FIG. 28 illustrates a structure of a meta sash to which the light-emitting module included in the light-emitting device package module is mounted, according to an embodiment of the inventive concept. FIG. 29 illustrates a color temperature spectrum related to light that is emitted from a light-emitting diode (LED) of the light-emitting device package module, according to an embodiment of the inventive concept. FIG. 30 illustrates a structure of a quantum dot that may be used in an LED of the light-emitting device package module, according to an embodiment of the inventive concept

As illustrated in FIG. 28, for example, each of the first circuit board 21 and the second circuit board 22 may include a circuit board unit 900 as shown in FIG. 28.

The circuit board includes an insulation resin 930 coated on a metal substrate 910, circuit patterns 941 and 942 formed in the insulation resin 930, and an LED module 950 mounted to be electrically connected with the circuit patterns 941 and 942. Here, the insulation resin 930 has a thickness equal to or less than 200 μm, and is coated on a sash in the form of a solid-state film laminated on a metal substrate, or is coated on the sash in a liquid state via a molding method using spin coating or a blade. Also, the circuit patterns 941 and 942 are formed in a manner in which a metal material such as copper is filled in shapes of the circuit patterns 941 and 942 that are engraved in the insulation resin 930.

The LED module 950 includes an LED chip 951, LED electrodes 952 and 953, a plastic molding case 954, and a lens 955.

In the present embodiment, the light-emitting device 10 corresponds to a package product including an LED chip. However, in another embodiment, the light-emitting device 10 may be an LED chip itself, and in this case, the LED chip that is a COB (Chip On Board) type may be mounted on the metal substrate 910 and then may directly achieve electrical connection with the metal substrate 910 via a flip chip bonding method or a wire bonding method.

A plurality of the light-emitting devices 10 may be arrayed along the metal substrate 910. In this case, the plurality of the light-emitting devices 10 may be homogeneous devices that generate light having the same wavelength. Alternatively, the plurality of the light-emitting devices 10 may be heterogeneous devices that generate light having different wavelengths.

For example, the light-emitting devices 10 may include at least one of a light-emitting device that is combination of a blue-light LED and a phosphor having a color of yellow, green, red, or orange and that emits white light, and a light-emitting device that emits a purple color, a blue color, a green color, a red color, or infrared light. In this case, a lighting apparatus may adjust a Color Rendering Index (CRI) of a solar level in sodium (Na) and also may generate a variety of white light from a candle temperature level (e.g., 1500K) to a blue sky temperature level (e.g., 12000K), and when required, the lighting apparatus may adjust a lighting color according to the ambient atmosphere or mood by generating visible light having a color of purple, blue, green, red, or orange, or infrared light. Also, the lighting apparatus may generate light having a special wavelength capable of promoting a growth of plants.

White light that corresponds to a combination of the blue-light LED and the yellow, green, and red phosphors, and/or green and red light-emitting devices may have at least two peak wavelengths and may be positioned at a line segment connecting (x, y) coordinates (0.4476, 0.4074), (0.3484, 0.3516), (0.3101, 0.3162), (0.3128, 0.3292), and (0.3333, 0.3333) of a CIE 1931 coordinate system. Alternatively, the white light may be positioned in a region surrounded by the line segment and a blackbody radiation spectrum. A color temperature of the white light may be between 2000k through 20000k. FIG. 29 illustrates a color temperature spectrum (e.g., a Planckian spectrum).

For example, phosphors that are used in an LED may have general formulas and colors as below.

Oxide-based phosphors: yellow and green Y₃Al₅O₁₂:Ce, Tb₃Al₅O₁₂:Ce, Lu₃Al₅O₁₂:Ce.

Silicate-based phosphors: yellow and green (Ba, Sr)₂SiO₄:Eu, yellow and orange (Ba,Sr)₃SiO₅:Ce.

Nitride-based phosphors: green β-SiAlON:Eu, yellow L3Si6O11:Ce, orange α-SiAlON:Eu, red CaAlSiN₃:Eu, Sr₂Si₅N₈:Eu, SrSiAl₄N₇:Eu.

In general, the general formulas of the phosphors must match with the stoichiometry, and each element may be substituted for another element in the same group of the periodic table. For example, Sr may be substituted for Ba, Ca, Mg, or the like of the alkaline-earth elements group II, and Y may be substituted for Tb, Lu, Sc, Gd, or the like of lanthanide-base elements. Also, Eu that is an activator may be substituted for Ce, Tb, Pr, Er, Yb or the like according to a desired energy level, and the activator may be solely used or a sub-activator may be additionally used for a characteristic change.

As a substitute for the phosphors, materials such as a quantum dot or the like may be used, and in this case, the LED, the phosphors, and the quantum dot may be combined or the LED and the quantum dot may be used.

The quantum dot may have a structure of a core (from 3 to 10 nm) such as CdSe, InP, or the like, a shell (from 0.5 to 2 nm) such as ZnS, ZnSe, or the like, and a Regand for stabilization of the core and the shell, and may realize various colors according to sizes. FIG. 30 illustrates an example of the structure of the quantum dot.

FIG. 31 illustrates phosphor types according to application fields of a white light-emitting device using a blue-light LED (from 440 to 460 nm).

Phosphors or quantum dots may be sprayed on an LED chip or a light-emitting device, may be used as a covering in the form of a thin-film, or may be attached in the form of a film-sheet or a ceramic phosphor sheet.

The phosphors or the quantum dots may be sprayed by using a dispensing method, a spray coating method, or the like. In this regard, the dispensing method includes a pneumatic method and a mechanical method such as a screw, a linear type, or the like. A jetting method may allow a dotting amount control via a minute-amount discharge operation, and a color-coordinates control via the dotting amount control. A method of collectively spraying phosphors on a wafer level or a substrate of the light-emitting device may facilitate a control of productivity and a thickness.

The method of covering the phosphors or the quantum dots in the form of a thin-film on the light-emitting device or the LED chip may be performed by using an electrophoretic deposition method, a screen printing method, or a phosphor molding method, and one of the aforementioned methods may be used according to whether it is required to cover side surfaces of the LED chip.

In order to control an efficiency of a long-wavelength light-emitting phosphor that re-absorbs light emitted at a short-wavelength and from among at least two types of phosphors having different emission wavelengths, the at least two types of phosphors having different emission wavelengths may be distinguished. In order to minimize wavelength re-absorption and interference of the LED chip and the at least two types of phosphors, a DBR (ODR) layer may be arranged between layers.

In order to form a uniform coating layer, the phosphors may be arranged in the form of a film or a ceramic sheet and then may be attached on the LED chip or the light-emitting device.

In order to vary a light efficiency and a light distribution characteristic, a light conversion material may be positioned in a remote manner, and here, the light conversion material may be positioned together with a light-transmitting polymer material, a glass material, or the like according to durability and heat resistance of the light conversion material.

Since the phosphor spraying technology performs a major role in the determination of a light characteristic of an LED device, various techniques to control a thickness of a phosphor-coated layer, uniform distribution of the phosphors, or the like are being studied. Also, the quantum dot may be positioned at the LED chip or the light-emitting device in the same manner as the phosphors. In this regard, the quantum dot may be positioned between glass materials or between light-transmitting polymer materials, thereby performing light conversion.

In order to protect the LED chip or the light-emitting device against an external environment or to improve an extraction efficiency of light that is externally emitted from the light-emitting device, a light-transmitting material as a filling material may be arranged on the LED chip or the light-emitting device.

Here, the light-transmitting material may be a transparent organic solvent including epoxy, silicone, a hybrid of epoxy and silicone, or the like, and may be used after being hardened via heating, light irradiation, a time-elapse, or the like.

With respect to silicone, polydimethyl siloxane is classified into a methyl-base, polymethylphenyl siloxane is classified into a phenyl-base, and depending on the methyl-base and the phenyl-base, silicon differs in a refractive index, a water-permeation rate, light transmittance, lightfastness, and heat-resistance. Also, silicon differs in a hardening time according to a cross linker and a catalyst, thereby affecting distribution of the phosphors.

The light extraction efficiency varies according to a refractive index of the filling material, and in order to minimize a difference between a refractive index of an outermost medium of emitted blue light of the LED chip and a refractive index of the blue light that is emitted to the outside air, at least two types of silicon having different refractive indexes may be sequentially stacked.

In general, the methyl-base has the most excellent heat-resistance, and variation due to a temperature increase is decreased in order of the phenyl-base, the hybrid, and epoxy. Silicone may be divided into a gel type, an elastomer type, and a resin type according to a hardness level.

The light-emitting device may further include a lens to radially guide light that is irradiated from a light source. In this regard, a pre-made lens may be attached on the LED chip or the light-emitting device, or a liquid organic solvent may be injected into a molding frame in which the LED chip or the light-emitting device is mounted and then may be hardened.

The lens may be directly attached on the filling material on the LED chip or may be separated from the filling material by bonding only an outer side of the light-emitting device and an outer side of the lens. The liquid organic solvent may be injected into the molding frame via injection molding, transfer molding, compression molding, or the like.

According to a shape (e.g., a concave shape, a convex shape, a concave-convex shape, a conical shape, a geometrical shape, of the like) of the lens, the light distribution characteristic of the light-emitting device may vary, and the shape of the lens may be changed according to requirements for the light efficiency and the light distribution characteristic.

The light-emitting device 10 may be formed as the LED chip having one of various structures or may be formed as an LED package including the LED chips and having one of various forms. Hereinafter, various types of the LED chip and the LED package that may be employed in lighting apparatuses according to one of more embodiments of the inventive concept will be described in detail.

### LED Chip—First Embodiment

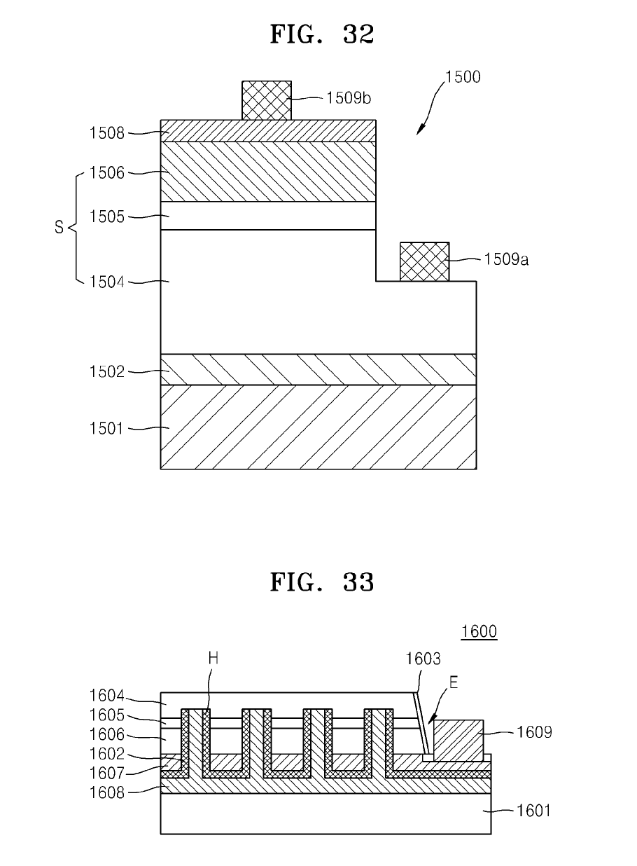

FIG. 32 illustrates an LED chip 1500 that may be used in the aforementioned light-emitting device package module, according to an embodiment of the inventive concept.

As illustrated in FIG. 32, the LED chip 1500 includes an emission stack S that is formed on a substrate 1501. The emission stack S includes a first conductive semiconductor layer 1504, an active layer 1505, and a second conductive semiconductor layer 1506.

Also, the LED chip 1500 includes an ohmic electrode layer 1508 formed on the second conductive semiconductor layer 1506, and a first electrode 1509a and a second electrode 1509b are formed on top surfaces of the first conductive semiconductor layer 1504 and the ohmic contact layer 1508, respectively.

Throughout the specification, terms such as ‘upper’, ‘top surface’, ‘lower’, ‘bottom surface’, ‘side surface’, or the like are based on drawings; thus, they may be changed according to a direction in which a device is actually disposed.

Hereinafter, major elements of the LED chip 1500 are described in detail.

According to necessities, the substrate 1501 may be formed of an insulating substrate, a conductive substrate, or a semiconductor substrate. For example, the substrate 1501 may be formed of sapphire, SiC, Si, MgAl₂O₄, MgO, LiAlO₂, LiGaO₂, or GaN. For an epitaxial growth of a GaN material, it is preferable to use a GaN substrate that is a homogeneous substrate; however, the GaN substrate has a high production cost due to difficulty in its manufacture.

An example of a heterogeneous substrate includes a sapphire substrate, silicon carbide (SiC) substrate, or the like, and in this regard, the sapphire substrate is used more than the SiC substrate, which is expensive. When the heterogeneous substrate is used, a defect such as dislocation or the like is increased due to a difference between lattice constants of a substrate material and a thin-film material. Also, due to a difference between thermal expansion coefficients of the substrate material and the thin-film material, the substrate 1501 may be bent when a temperature is changed, and the bend causes a crack of a thin-film. The aforementioned problem may be decreased by using a buffer layer 1502 between the substrate 1501 and the emission stack S that includes a GaN material.

In order to improve an optical or electrical characteristic of the LED chip 1500 before or after an LED structure growth, the substrate 1501 may be completely or partly removed or may be patterned while a chip is manufactured.

For example the sapphire substrate may be separated in a manner in which a laser is irradiated to an interface between the sapphire substrate and a semiconductor layer, and a silicon substrate or the SiC substrate may be removed by using a grinding method, an etching method, or the like.

When the substrate 1501 is removed, another supporting substrate may be used, and the supporting substrate may be bonded to the other side of an original growth substrate by using a reflective metal material or may be formed by inserting a reflection structure into an adhesion layer, so as to improve an optical efficiency of the LED chip 1500.

A patterning operation on a substrate is performed by forming an uneven or sloped surface on a main side (e.g., a top surface or both surfaces) or side surfaces of the substrate before or after a growth of an LED structure, and by doing so, a light extraction efficiency is improved. A size of a pattern may be selected in a range from 5 nm to 500 μm, and in order to improve the light extraction efficiency, a regular pattern or an irregular pattern may be selected. In addition, a shape of the pattern may be a column, a mountain, a hemisphere, a polygonal shape, or the like.

The sapphire substrate includes crystals having a hexagonal-rhombohedral (Hexa-Rhombo R3c) symmetry in which lattice constants of the crystal in c-axial and a-lateral directions are 13.001 and 4.758, respectively, and the crystal has a C (0001) surface, an A (1120) surface, an R(1102) surface, or the like. In this case, the C (0001) surface easily facilitates the growth of a nitride thin-film, and is stable at a high temperature, so that the C (0001) surface is commonly used as a substrate for the growth of nitride.

The substrate is formed as an Si substrate that is more appropriate for a large diameter and has a relatively low price, so that mass production may be improved. However, since the Si substrate having a (111) surface as a substrate surface has a lattice constant difference of about 17% with GaN, a technology is required to suppress occurrence of a defective crystal due to the lattice constant difference. In addition, a thermal expansion difference between silicon and GaN is about 56%, so that a technology is required to suppress wafer bend caused due to the thermal expansion difference. Due to the wafer bend, a GaN thin-film may have a crack, and it may be difficult to perform a process control such that dispersion of emission wavelength in a same wafer may be increased.

Since the Si substrate absorbs light generated in a GaN-based semiconductor, an external quantum efficiency of the light-emitting device 10 may deteriorate, so that, the Si substrate is removed when required, and a supporting substrate such as Si, Ge, SiAl, ceramic, or metal substrates including a reflective layer may be additionally formed and then be used.

When the GaN thin-film is grown on a heterogeneous substrate such as the Si substrate, a dislocation density may be increased due to a mismatch between lattice constants of a substrate material and a thin-film material, and the crack and the bend may occur due to the thermal expansion difference. In order to prevent the dislocation and the crack of the emission stack S, the buffer layer 1502 is disposed between the substrate 1501 and the emission stack S. The buffer layer 1502 decreases the dispersion of the emission wavelength of the wafer by adjusting a bending level of the substrate while the active layer is grown.

The buffer layer 1502 may be formed of AlₓIn_{y}Ga_{1-x-y}N (0<x<1, 0<y<1), in particular, GaN, MN, AlGaN, InGaN, or InGaNAlN, and when required, the buffer layer 1502 may be formed of ZrB₂, HfB₂, ZrN, HfN, TiN, or the like. Also, the buffer layer 1502 may be formed by combining a plurality of layers or by gradually varying composition of one of the aforementioned materials.

Since the Si substrate and the GaN thin-film has the large thermal expansion difference, when the GaN thin-film is grown on the Si substrate, the GaN thin-film is grown at a high temperature and then is cooled at a room temperature. At this time, a tensile stress may be applied to the GaN thin-film due to the thermal expansion difference between the Si substrate and the GaN thin-film, such that a crack in the Si substrate may easily occur. In order to prevent the crack, a compressive stress may be applied to the GaN thin-film while the GaN thin-film is grown, so that the tensile stress may be compensated.

Due to the lattice constant difference between the Si substrate and the GaN thin-film, the Si substrate may be defective. When the Si substrate is used, a buffer layer having a composite structure is used so as to simultaneously perform a defect control and a stress control to suppress the bend.

For example, AlN is first formed on the substrate 1501. In order to prevent reaction between Si and Ga, it is required to use a material that does not contain Ga. Not only AlN but also SiC may be used. AlN is grown by using Al and N sources at a temperature between 400 through 1300 degrees. When required, an AlGaN intermediate layer may be inserted into a plurality of AlN layers so as to control a stress.

The emission stack S having a multi-layer structure of the group-III nitride semiconductor is now described in detail. The first and second conductive semiconductor layers 1504 and 1506 may be formed of semiconductors that are doped with n-type and p-type impurities, respectively, or vice versa. For example, each of the first and second conductive semiconductor layers 1504 and 1506 may be formed of, but are not limited to, the group-III nitride semiconductor, e.g., a material having a composition of AlₓIn_{y}Ga_{1-x-y}N (0<x<1, 0<y<1, 0<x+y<1). In another embodiment, each of the first and second conductive semiconductor layers 1504 and 1506 may be formed of a material including an AlGaInP-based semiconductor, an AlGaAs-based semiconductor, or the like.

Each of the first and second conductive semiconductor layers 1504 and 1506 may have a single-layer structure. However, when required, each of the first and second conductive semiconductor layers 1504 and 1506 may have a multi-layer structure including a plurality of layers having different compositions or thicknesses. For example, each of the first and second conductive semiconductor layers 1504 and 1506 may have a carrier injection layer capable of improving an efficiency of electron and hole injection, and may also have a superlattice structure having various forms.

The first conductive semiconductor layer 1504 may further include a current diffusion layer (not shown) adjacent to the active layer 1505. The current diffusion layer may have a structure in which a plurality of InₓAl_{y}Ga_{(1-x-y)}N layers having different compositions or different impurity ratios are repeatedly stacked, or may be partially formed of an insulation material layer.

The second conductive semiconductor layer 1506 may further include an electron block layer (not shown) adjacent to the active layer 1505. The electron block layer may have a structure in which a plurality of InₓAl_{y}Ga_{(1-x-y)}N layers having different compositions are stacked or may have at least one layer formed of Al_{y}Ga_{(1-y)}N. Since the electron block layer has a bandgap larger than the active layer 1505, the electron block layer prevents electrons from entering to the second conductive semiconductor layer 1506 (that is a p-type).

The emission stack S is formed by using an MOCVD apparatus. In more detail, the emission stack S is formed in a manner in which a reaction gas such as an organic metal compound gas (e.g., trimethyl gallium (TMG), trimethyl aluminum (TMA), or the like) and a nitrogen containing gas (e.g. ammonia (NH₃), or the like) are injected into a reaction container in which the substrate 1501 is arranged and the substrate 1501 is maintained at a high temperature of about 900 through 1100 degrees, while a gallium-based compound semiconductor is grown on the substrate 1501. If required, an impurity gas is injected, so that the gallium-based compound semiconductor is stacked as an undoped-type, an n-type, or a p-type. Si is well known as n-type impurity. Zn, Cd, Be, Mg, Ca, Ba, or the like, in particular, Mg and Zn, may be used as p-type impurity.

The active layer 1505 that is disposed between the first and second conductive semiconductor layers 1504 and 1506 may have a multi-quantum well (MQW) structure in which a quantum well layer and a quantum barrier layer are alternately stacked. For example, in a case of a nitride semiconductor, the active layer 1505 may have a GaN/InGaN structure. However, in another embodiment, the active layer 1505 may have a single-quantum well (SQW) structure.

The ohmic electrode layer 1508 may decrease an ohmic contact resistance by relatively increasing an impurity density, so that the ohmic electrode layer 1508 may decrease an operating voltage and may improve a device characteristic. The ohmic electrode layer 1508 may be formed of GaN, InGaN, ZnO, or a graphene layer.

The first electrode 1509a or the second electrode 1509b may include a material such as Ag, Ni, Al, Rh, Pd, Ir, Ru, Mg, Zn, Pt, Au, or the like, or may have a multi-layer structure including Ni/Ag, Zn/Ag, Ni/Al, Zn/Al, Pd/Ag, Pd/Al, Ir/Ag. Ir/Au, Pt/Ag, Pt/Al, Ni/Ag/Pt, or the like.

While the LED chip 1500 shown in FIG. 32 has a structure in which the first electrode 1509a, the second electrode 1509b, and a light extraction surface face the same side, the LED chip 1500 may have various structures such as a flip-chip structure in which the first electrode 1509a and the second electrode 1509b face the opposite side of the light extraction surface, a vertical structure in which the first electrode 1509a and the second electrode 1509b are formed on opposite surfaces, a vertical and horizontal structure employing an electrode structure in which a plurality of vias are formed in a chip so as to increase an efficiency of current distribution and heat dissipation.

### LED Chip—Second Embodiment

FIG. 33 illustrates an LED chip 1600 having a structure useful for increasing an efficiency of current distribution and heat dissipation, when a large area light-emitting device chip for a high output for a lighting apparatus is manufactured, according to another embodiment of the inventive concept.

As illustrated in FIG. 33, the LED chip 1600 includes a first conductive semiconductor layer 1604, an active layer 1605, a second conductive semiconductor layer 1606, a reflective layer 1603 and an electrode 1609 having a gap E between them, a second electrode layer 1607, an insulating layer 1602, a first electrode layer 1608, and a substrate 1601. Here, in order to be electrically connected to the first conductive semiconductor layer 1604, the first electrode layer 1608 includes one or more contact holes H that are electrically insulated from the second conductive semiconductor layer 1606 and the active layer 1605 and that extend from a surface of the first electrode layer 1608 to a portion of the first conductive semiconductor layer 1604. In the present embodiment, the first electrode layer 1608 is not an essential element.

The contact hole H extends from an interface of the first electrode layer 1608 to an inner surface of the first conductive semiconductor layer 1604 via the second conductive semiconductor layer 1606 and the active layer 1605. The contact hole H extends to an interface between the active layer 1605 and the first conductive semiconductor layer 1604, and more preferably, the contact hole H extends to the portion of the first conductive semiconductor layer 1604. Since the contact hole H functions to perform electrical connection and current distribution of the first conductive semiconductor layer 1604, the contact hole H achieves its purpose when the contact hole H contacts the first conductive semiconductor layer 1604. Thus, it is not required for the contact hole to extend to an outer surface of the first conductive semiconductor layer 1604.

The second electrode layer 1607 formed on the second conductive semiconductor layer 1606 may be formed of a material selected from the group consisting of Ag, Ni, Al, Rh, Pd, Ir, Ru, Mg, Zn, Pt, and Au, in consideration of a light reflection function and an ohmic contact with the second conductive semiconductor layer 1606, and may be formed via a sputtering process or a deposition process.

The contact hole H has a shape that penetrates through the second electrode layer 1607, the second conductive semiconductor layer 1606, and the active layer 1605 so as to be connected with the first conductive semiconductor layer 1604. The contact hole H may be formed via an etching process using ICP-RIE or the like.

The insulating layer 1602 is formed to cover side walls of the contact hole H and a top surface of the second conductive semiconductor layer 1606. In this case, a portion of the first conductive semiconductor layer 1604 that corresponds to a bottom surface of the contact hole H may be exposed. The insulating layer 1602 may be formed by depositing an insulation material such as SiO₂, SiOₓN_{y}, SiₓN_{y}, or the like.

The second electrode layer 1607 that includes a conductive via formed by filling a conductive material is formed in the contact hole H. Afterward, the substrate 1601 is formed on the first electrode layer 1608. In this structure, the substrate 1601 may be electrically connected to the first conductive semiconductor layer 1604 by the conductive via that contacts the first conductive semiconductor layer 1604.

The substrate 1601 may be formed of, but is not limited to, a material selected from the group consisting of Au, Ni, Al, Cu, W, Si, Se, GaAs, SiAl, Ge, SiC, MN, Al₂O₃, GaN, and AlGaN, via a plating process, a sputtering process, a deposition process, or an adhesion process.

In order to decrease a contact resistance of the contact hole H, a total number of the contact holes H, a shape of the contact hole H, a pitch of the contact hole H, a contact area of the contact hole H with respect to the first and second conductive semiconductor layers 1604 and 1606, or the like may be appropriately adjusted. Since the contact holes H are arrayed in various forms along lines and columns, a current flow may be improved. In this case, the conductive via is surrounded by an insulation unit, so that the conductive via may be electrically separated from the active layer 1605 and the second conductive semiconductor layer 1606.

### LED Chip—Third Embodiment

Since an LED lighting apparatus provides an improved heat dissipation characteristic, it is preferable to apply an LED chip having a small calorific value to the light-emitting device package module 100, in consideration of a total heat dissipation performance. An example of the LED chip may be an LED chip having a nano structure (hereinafter, referred to as a “nano LED chip”).

An example of the nano LED chip includes a core-shell type nano LED chip that has recently been developed. The core-shell type nano LED chip generates a relatively small amount of heat due to its small combined density, and increases its emission area by using the nano structure so as to increase an emission efficiency. Also, the core-shell type nano LED chip may obtain a non-polar active layer, thereby preventing efficiency deterioration due to polarization, so that a drop characteristic may be improved.

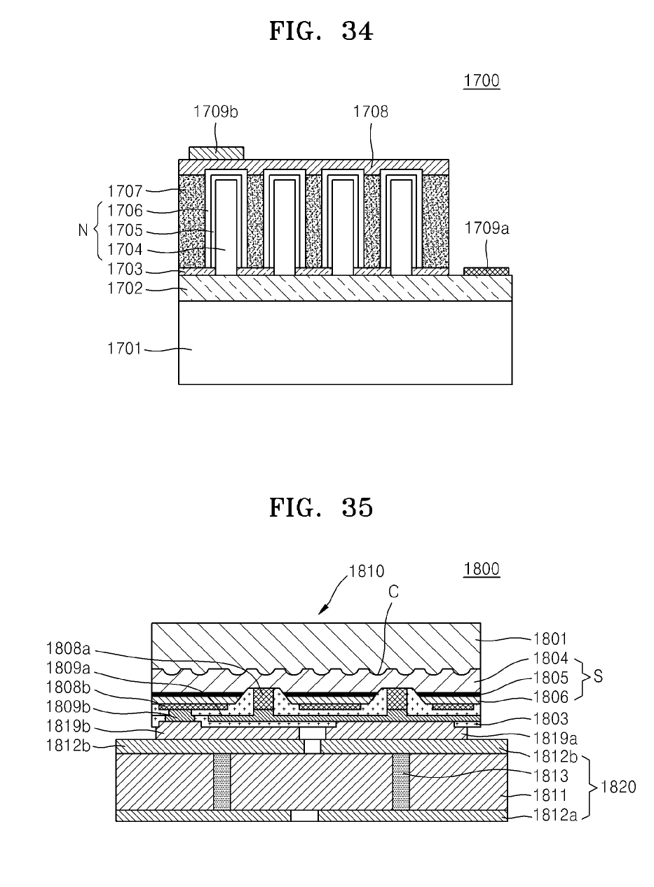

FIG. 34 illustrates a nano LED chip 1700 that may be applied to the lighting apparatus, according to another embodiment of the inventive concept.

As illustrated in FIG. 34, the nano LED chip 1700 includes a plurality of nano emission structures N that are formed on a substrate 1701. In the present embodiment, the nano emission structure N has a rod structure as a core-shell structure, but in another embodiment, the nano emission structure N may have a different structure such as a pyramid structure.

The nano LED chip 1700 includes a base layer 1702 formed on a substrate 1701. The base layer 1702 may be a layer to provide a growth surface for the nano emission structure N and may be formed of a first conductive semiconductor. A mask layer 1703 having open areas for a growth of the nano emission structures N (in particular, a core) may be formed on the base layer 1702. The mask layer 1703 may be formed of a dielectric material such as SiO₂ or SiNx.

In the nano emission structure N, a first conductive nano core 1704 is formed by selectively growing the first conductive semiconductor by using the mask layer 1703 having open areas, and an active layer 1705 and a second conductive semiconductor layer 1706 are formed as a shell layer on a surface of the first conductive nano core 1704. By doing so, the nano emission structure N may have a core-shell structure in which the first conductive semiconductor is a nano core, and the active layer 1705 and the second conductive semiconductor layer 1706 that surround the nano core are the shell layer.

In the present embodiment, the nano LED chip 1700 includes a filling material 1707 that fills gaps between the nano emission structures N. The filling material 1707 may structurally stabilize the nano emission structures N. The filling material 1707 may include, but is not limited to, a transparent material such as SiO₂. An ohmic contact layer 1708 may be formed on the nano emission structure N so as to contact the second conductive semiconductor layer 1706. The nano LED chip 1700 includes first and second electrodes 1709a and 1709b that contact the base layer 1702, which is formed of the first conductive semiconductor, and the ohmic contact layer 1708, respectively.

By varying a diameter, a component, or a doping density of the nano emission structure N, light having at least two different wavelengths may be emitted from one device. By appropriately adjusting the light having the different wavelengths, white light may be realized in the one device without using a phosphor. In addition, by combining the one device with another LED chip or combining the one device with a wavelength conversion material such as a phosphor, light having desired various colors or white light having different color temperatures may be realized.

### LED Chip—Fourth Embodiment

FIG. 35 illustrates a semiconductor light-emitting device 1800 that is a light source to be applied to the light-emitting device package module 100 and that includes an LED chip 1810 mounted on a mounting substrate 1820, according to an embodiment of the inventive concept.

The semiconductor light-emitting device 1800 shown in FIG. 35 includes the mounting substrate 1820 and the LED chip 1810 that is mounted on the mounting substrate 1820. The LED chip 1810 is different from the LED chips in the aforementioned embodiments.

The LED chip 1810 includes an emission stack S disposed on a surface of the substrate 1801, and first and second electrodes 1808a and 1808b disposed on the other surface of the substrate 1801 with respect to the emission stack S. Also, the LED chip 1810 includes an insulation unit 1803 to cover the first and second electrodes 1808a and 1808b.

The first and second electrodes 1808a and 1808b may include first and second electrode pads 1819a and 1819b due to first and second electric power connection units 1809a and 1809b.

The emission stack S may include a first conductive semiconductor layer 1804, an active layer 1805, and a second conductive semiconductor layer 1806 that are sequentially disposed on the substrate 1801. The first electrode 1808a may be provided as a conductive via that contacts the first conductive semiconductor layer 1804 by penetrating through the second conductive semiconductor layer 1806 and the active layer 1805. The second electrode 1808b may contact the second conductive semiconductor layer 1806.

The insulation unit 1803 may have an open area to expose a portion of the first and second electrodes 1808a and 1808b, and the first and second electrode pads 1819a and 1819b may contact the first and second electrodes 1808a and 1808b.

The first and second electrodes 1808a and 1808b may have a single-layer structure or a multi-layer structure formed of a conductive material making an ohmic contact with the first and second conductive semiconductor layers 1804 and 1806, respectively. For example, the first and second electrodes 1808a and 1808b may be formed by depositing or sputtering at least one material selected from the group consisting of Ag, Al, Ni, Cr, and transparent conductive oxide (TCO). The first and second electrodes 1808a and 1808b may be disposed in the same direction, and as will be described later, the first and second electrodes 1808a and 1808b may be mounted in the form of a flip-chip in a lead frame. In this case, the first and second electrodes 1808a and 1808b may be disposed to face in the same direction.

In particular, a first electric power connection unit 1809a may be formed by the first electrode 1808a having a conductive via that penetrates through the active layer 1805 and the second conductive semiconductor layer 1806 and then is connected to the first conductive semiconductor layer 1804 in the emission stack S.

In order to decrease a contact resistance between the conductive via and the first electric power connection unit 1809a, a total number, shapes, pitches, a contact area with the first conductive semiconductor layer 1804, or the like of the conductive via and the first electric power connection unit 1809a may be appropriately adjusted. Since the conductive via and the first electric power connection unit 1809a are arrayed in rows and columns, a current flow may be improved.

An electrode structure of the other side of the semiconductor light-emitting device 1800 may include the second electrode 1808b that is directly formed on the second conductive semiconductor layer 1806, and the second electric power connection unit 1809b that is formed on the second electrode 1808b. The second electrode 1808b may function to form electrical ohmic connection with the second electric power connection unit 1809b and may be formed of a light reflection material, so that, when the LED chip 1810 is mounted as a flip-chip structure as illustrated in FIG. 35, the second electrode 1808b may efficiently discharge light, which is emitted from the active layer 1805, toward the substrate 1801. Obviously, according to a major light emission direction, the second electrode 1808b may be formed of a light-transmitting conductive material such as transparent conductive oxide.

The aforementioned two electrode structures may be electrically separated from each other by using the insulation unit 1803. Any material or any object having an electrical insulation property may be used as the insulation unit 1803, but it is preferable to use a material having a low light-absorption property. For example, silicon oxide or silicon nitride such as SiO₂, SiOxNy, SixNy or the like may be used. When required, the insulation unit 1803 may have a light reflection structure in which a light reflective filler is distributed throughout a light transmitting material.

The first and second electrode pads 1819a and 1819b may be connected to the first and second electric power connection units 1809a and 1809b, respectively, and thus may function as external terminals of the LED chip 1810. For example, the first and second electrode pads 1819a and 1819b may be formed of Au, Ag, Al, Ti, W, Cu, Sn, Ni, Pt, Cr, NiSn, TiW, AuSn, or a eutectic alloy thereof. In this case, when the first and second electrode pads 1819a and 1819b are mounted on the mounting substrate 1820, the first and second electrode pads 1819a and 1819b may be bonded to mounting substrate 1820 by using eutectic metal, so that a separate solder bump that is generally used in flip-chip bonding may not be used. Compared to a case of using the solder bump, the mounting method using the eutectic metal may achieve a more excellent heat dissipation effect. In this case, in order to obtain the excellent heat dissipation effect, the first and second electrode pads 1819a and 1819b may be formed while having large areas.

The substrate 1801 and the emission stack S may be understood by referring to the description a mention above, unless contrary description is provided. Also, although not particularly illustrated in FIG. 35, a buffer layer (not shown) may be formed between the emission stack S and the substrate 1801, and in this regard, the buffer layer may be formed as a undoped semiconductor layer including nitride or the like, so that the buffer layer may decrease a lattice defect of an emission structure that is grown on the buffer layer.

The substrate 1801 may have first and second primary surfaces that face each other, and in this regard, a convex-concave structure C may be formed on at least one of the first and second primary surfaces. The convex-concave structure C that is arranged on one surface of the substrate 1801 may be formed of the same material as the substrate 1801 since a portion of the substrate 1801 is etched, or may be formed of a different material from the substrate 1801.

As in the present embodiment, since the convex-concave structure C is formed at an interface between the substrate 1801 and the first conductive semiconductor layer 1804, a path of light emitted from the active layer 1805 may vary, such that a rate of light absorbed in the semiconductor layer may be decreased and a light-scattering rate may be increased; thus, the light extraction efficiency may be increased.

In more detail, the convex-concave structure C may have a regular shape or an irregular shape. Heterogeneous materials that form the convex-concave structure may include a transparent conductor, a transparent insulator, or a material having excellent reflectivity, and in this regard, the transparent insulator may include, but is not limited to, SiO₂, SiNx, Al₂O₃, HfO, TiO₂ or ZrO, the transparent conductor may include, but is not limited to, TCO such as indium oxide containing ZnO or an additive including Mg, Ag, Zn, Sc, Hf, Zr, Te, Se, Ta, W, Nb, Cu, Si, Ni, Co, Mo, Cr, or Sn, and the reflective material may include, but is not limited to, Ag, Al, or DBR that is formed of a plurality of layers having different refractive indexes.

The substrate 1801 may be removed from the first conductive semiconductor layer 1804. In order to remove the substrate 1801, a laser lift off (LLO) process using a laser, an etching process, or a grinding process may be performed. After the substrate 1801 is removed, the convex-concave structure C may be formed on a top surface of the first conductive semiconductor layer 1804.

As illustrated in FIG. 35, the LED chip 1810 is mounted on the mounting substrate 1820. The mounting substrate 1820 has a structure in which upper and lower electrode layers 1812b and 1812a are formed on a top surface and a bottom surface of a substrate body 1811, respectively, and a via 1813 penetrates through the substrate body 1811 so as to connect the upper and lower electrode layers 1812b and 1812a. The substrate body 1811 may be formed of resin, ceramic, or metal, and the upper and lower electrode layers 1812b and 1812a may be metal layers including Au, Cu, Ag, Al, or the like.

An example of a substrate on which the LED chip 1810 is mounted is not limited to the mounting substrate 1820 of FIG. 35, and thus any substrate having a wiring structure to drive the LED chip 1810 may be used. For example, it is possible to provide a package structure in which the LED chip 1810 is mounted in a package body having a pair of lead frames.

### LED Chip—Additional Embodiment

An LED chip having one of various structures may be used, other than the aforementioned LED chips. For example, it is possible to use an LED chip having a light extraction efficiency that is significantly improved by interacting a quantum well exciton and surface-plasmon polaritons (SPP) formed at an interface between metal and dielectric layers of the LED chip.

### LED Package

The aforementioned various LED chips may be mounted as bare chips on a circuit board and then may be used in the lighting apparatus. However, the LED chips may also alternatively be used in various package structures that are mounted in a package body having a pair of electrodes.

A package including the LED chip (hereinafter, referred to as an LED package) may have not only an external terminal structure that is easily connected to an external circuit, but also may have a heat dissipation structure for improvement of a heat dissipation characteristic of the LED chip and various optical structures for improvement of a light characteristic of the LED chip. For example, the various optical structures may include a wavelength conversion unit that converts light emitted from the LED chip into light having a different wavelength, or may include a lens structure for improvement of a light distribution characteristic of the LED chip.

### Example of the LED Package—Chip Scale Package (CSP)

The example of the LED package that may be used in the lighting apparatus may include an LED chip package having a CSP structure.

The CSP may reduce a size of the LED chip package, may simplify the manufacturing procedure, and may be appropriate for mass production. In addition, an LED chip, wavelength conversion materials such as phosphors, and an optical structure such as a lens may be integrally manufactured, so that the CSP may be designed as appropriate for the lighting apparatus.

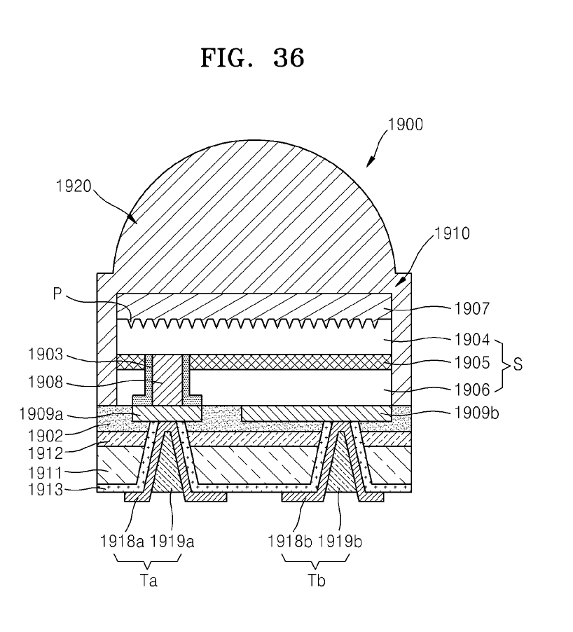

FIG. 36 illustrates an example of the CSP that has a package structure in which an electrode is formed via a bottom surface of an LED 1910 in an opposite direction of a primary light extraction surface, and a phosphor layer 1907 and a lens 1920 are integrally formed, according to an embodiment of the inventive concept.

A CSP 1900 shown in FIG. 36 includes an emission stack S disposed on a mounting substrate 1911, first and second terminals Ta and Tb, the phosphor layer 1907, and the lens 1920.

The emission stack S has a stack structure including first and second semiconductor layers 1904 and 1906, and an active layer 1905 disposed between the first and second semiconductor layers 1904 and 1906. In the present embodiment, the first and second semiconductor layers 1904 and 1906 may be p-type and n-type semiconductor layers, respectively, and may be formed of a nitride semiconductor such as AlₓIn_{y}Ga_{(1-x-y)}N (0<x<1, 0<y<1, 0<x+y<1). Alternatively, the first and second semiconductor layers 1904 and 1906 may be formed of a GaAs-based semiconductor or a GaP-based semiconductor, other than the nitride semiconductor.

The active layer 1905 that is disposed between the first and second semiconductor layers 1904 and 1906 may emit light that has a predetermined energy due to recombination of electrons and holes and may have a MQW structure in which a quantum well layer and a quantum barrier layer are alternately stacked. The MQW structure may include an InGaN/GaN structure or a AlGaN/GaN structure.

The first and second semiconductor layers 1904 and 1906, and the active layer 1905 may be formed via a semiconductor layer growing procedure such as MOCVD, MBE, HYPE, or the like that is well known in the art.

In the LED 1910 shown in FIG. 36, a growth substrate is already removed, and a concave-convex structure P may be formed on a surface of the LED 1910 from which the growth substrate is removed. Also, the phosphor layer 1907 is formed as a light conversion layer on the surface whereon the concave-convex structure P is formed.

Similar to the LED chip 1810 of FIG. 35, the LED 1910 has first and second electrodes 1909a and 1909b that contact the first and second semiconductor layers 1904 and 1906, respectively. The first electrode 1909a has a conductive via 1908 that contacts the first semiconductor layer 1904 by penetrating through the second semiconductor layer 1906 and the active layer 1905. The conductive via 1908 has an insulating layer 1903 formed between the active layer 1905 and the second semiconductor layer 1906, thereby preventing a short.

Referring to FIG. 36, one conductive via 1908 is arranged, but in another embodiment, at least two conductive vias 1908 may be arranged for improved current distribution and may be arrayed in various forms.

The mounting substrate 1911 is a supporting substrate such as a silicon substrate to be easily applied to a semiconductor procedure, but examples of the mounting substrate 1911 may vary. The mounting substrate 1911 and the LED 1910 may be bonded to each other via bonding layers 1902 and 1912. The bonding layers 1902 and 1912 may be formed of an electrical insulation material or an electrical conduction material. In this regard, examples of the electrical insulation material may include oxide such as SiO₂, SiN, or the like, or resin materials including a silicon resin, an epoxy resin, or the like, and examples of the electrical conduction material may include Ag, Al, Ti, W, Cu, Sn, Ni, Pt, Cr, NiSn, TiW, AuSn, or a eutectic metal thereof. The bonding process may be performed in a manner in which the bonding layers 1902 and 1912 are arranged on bonding surfaces of the LED 1910 and the mounting substrate 1911 and then are bonded together.

A via that penetrates through the mounting substrate 1911 is formed at a bottom surface of the mounting substrate 1911 so as to contact the first and second electrodes 1909a and 1909b of the bonded LED 1910. Then, an insulator 1913 may be formed on a side surface of the via and the bottom surface of the mounting substrate 1911. When the mounting substrate 1911 is formed as a silicon substrate, the insulator 1913 may be arranged as a silicon oxide layer formed via a thermal oxidation procedure. By filling the via with a conductive material, the first and second terminals Ta and Tb are formed to be connected to the first and second electrodes 1909a and 1909b. The first and second terminals Ta and Tb may include seed layers 1918a and 1918b, and plating charging units 1919a and 1919b that are formed by using the seed layers 1918a and 1918b via a plating procedure.

While the inventive concept has been particularly shown and described with reference to exemplary embodiments thereof, it will be understood that various changes in form and details may be made therein without departing from the spirit and scope of the following claims.

What is claimed is:

1. A light-emitting device package module comprising:
a light-emitting device;
a first circuit board receiving the light-emitting device, and electrically connected with the light-emitting device; and
a second circuit board assembled with the first circuit board by using a connection member, and electrically connected with the first circuit board.

2. The light-emitting device package module of claim 1, wherein the first circuit board is a quadrangular plate, and the second circuit board comprises a first-side second circuit board assembled at a first side of the first circuit board and a second-side second circuit board assembled at a second side of the first circuit board.

3. The light-emitting device package module of claim 1, wherein the second circuit board is a multi-step plate comprising a first step portion having a first height, and a second step portion connected to the first step portion and having a second height.

4. The light-emitting device package module of claim 3, wherein the second circuit board further comprises a sloped portion that slopes between the first step portion and the second step portion.

5. The light-emitting device package module of claim 4, wherein the sloped portion of the second circuit board is assembled with the first step portion and the second step portion by using the connection member.

6. The light-emitting device package module of claim 1, wherein the connection member comprises:
a forced-engagement protrusion unit disposed on the first circuit board; and
a forced-engagement groove unit disposed on the second circuit board and engaged to the forced-engagement protrusion unit.

7. The light-emitting device package module of claim 6, wherein the forced-engagement protrusion unit comprises one or more quadrangular protrusions and the forced-engagement groove unit comprises one or more quadrangular grooves corresponding to the one or more quadrangular protrusions.

8. The light-emitting device package module of claim 1, wherein the connection member comprises:
a through hole formed in the first circuit board; and
a through hole protrusion formed on the second circuit board and inserted into the through hole.

9. The light-emitting device package module of claim 1, wherein the connection member is formed of at least one selected from the group consisting of a connection pin, a hinge, a screw, a bolt, a rivet, a connection belt, an adhesive, a welding agent, a snap button, a Velcro tape, a magnet, and a combination thereof.

10. The light-emitting device package module of claim 1, wherein the first circuit board comprises a first wiring layer electrically connected to the light-emitting device, and a first connection terminal formed at an end of the first wiring layer, and
the second circuit board comprises a second connection terminal electrically connected to the first connection terminal, a second wiring layer electrically connected to the second connection terminal, and an external connection terminal disposed at an end of the second wiring layer and connected to an external power connector.

11. The light-emitting device package module of claim 10, wherein the first connection terminal and the second connection terminal are contact-type terminals that are respectively disposed on a contact surface of the first circuit board and a contact surface of the second circuit board when the first circuit board and the second circuit board are assembled.

12. The light-emitting device package module of claim 10, wherein an electric power transfer medium is arranged between the first connection terminal and the second connection terminal.

13. The light-emitting device package module of claim 1, further comprising a heat dissipation member thermally contacting the light-emitting device and externally dissipating heat generated in the light-emitting device.

14. The light-emitting device package module of claim 1, further comprising an elastic member disposed between the first circuit board and the second circuit board so as to lessen a shock and collision between the first circuit board and the second circuit board.

15. A light-emitting device package module comprising:
a light-emitting device;
a first circuit board receiving the light-emitting device; and
a second circuit board assembled with the first circuit board using a connection member,
wherein the second circuit board is a multi-step plate comprising a first step portion having a first height and a second step portion connected to the first step portion and having a second height.

16. A lighting device having a light-emitting device package module comprising:
a frame;
a transparent cover;
a light-emitting device;
a first circuit board receiving the light-emitting device;
a second circuit board assembled with the first circuit board using a connection member,
wherein the second circuit board is a multi-step plate comprising a first step portion having a first height and a second step portion connected to the first step portion and having a second height; and
wherein the frame and the transparent cover in combination define a space which houses the light-emitting device, the first circuit board and the second circuit board.

17. The lighting device of claim 16, wherein the second circuit board further comprises a sloped portion between the first and second steps.

18. The lighting device of claim 17, wherein the light-emitting device is configured to be disposed within an enclosure comprising the frame and the transparent cover based on at least one of the angle of the sloped portion and the shape of the sloped portion.

19. The lighting device of claim 16, wherein the lighting device is a vehicle light comprising one of a head light, a rear light, a display light, an inner light and a guide light.
